(19) United States
(12) Patent Application Publication
(10) Pub. No.: US 2012/0216743 A1
(43) Pub. Date: Aug. 30, 2012

(54) ATTACHMENT FOR SUBSTRATES HAVING DIFFERENT DIAMETERS, SUBSTRATE PROCESSING APPARATUS, AND METHOD OF MANUFACTURING SUBSTRATE OR SEMICONDUCTOR DEVICE

(75) Inventors: Takeshi Itoh, Toyama (JP); Akinori Tanaka, Toyama (JP)

(73) Assignee: HITACHI KOKUSAI ELECTRIC INC., Tokyo (JP)

(21) Appl. No.: 13/407,225

(22) Filed: Feb. 28, 2012

(30) Foreign Application Priority Data
Feb. 28, 2011 (JP) 2011-041216
Jan. 16, 2012 (JP) 2012-001176

(51) Int. Cl. H01L 21/205; F16M 13/00; C30B 25/02

(52) U.S. Cl. 117/88; 118/729; 248/309.1; 211/86.01; 257/E21.102

(57) ABSTRACT

A downsized substrate may be housed in a substrate accommodation vessel (FOUP) constituting a transfer system corresponding to a large diameter substrate. An attachment includes an upper plate and a lower plate supported by a first support groove that can support an 8-inch wafer, and holding columns installed at the upper plate and the lower plate and including a second support groove that can support a 2-inch wafer (if necessary, via a wafer holder and a holder member). Accordingly, the 2-inch wafer can be housed in a pod corresponding to the 8-inch wafer, and the pod, which is a transfer system, can be standardized to reduce cost of a semiconductor manufacturing apparatus. In addition, a distance from each gas supply nozzle to the wafer can be increased to sufficiently mix reactive gases before arrival at the wafer and improve film-forming precision to the wafer.

### CROSS-REFERENCE TO RELATED PATENT APPLICATION

This U.S. non-provisional patent application claims priority under 35 U.S.C. §119 of Japanese Patent Application No. 2011-041216, filed on Feb. 28, 2011, and Japanese Patent Application No. 2012-001176, filed on Jan. 16, 2012, in the Japanese Patent Office, the entire contents of which are hereby incorporated by reference.

### BACKGROUND OF THE INVENTION

1. Field of the Invention

The present invention relates to an attachment for substrates having different diameters, that is capable of housing substrates having different diameters in one accommodation vessel (FOUP), a substrate processing apparatus, and a method of manufacturing a substrate or a semiconductor device.

2. Description of the Related Art

Since silicon carbide (SiC) has a higher withstand voltage or thermal conductivity than silicon (Si), SiC is attracting attention as a device material for, in particular, a power device. Meanwhile, as is well known in the art, since SiC has a small impurity diffusion coefficient, manufacture of a crystalline substrate or a semiconductor device is difficult in comparison with Si. For example, since an epitaxial film-forming temperature of SiC is about 1,500° C. to 1,800° C. in comparison with Si having an epitaxial film-forming temperature of about 900° C. to 1,200° C., technical research on a heat-resistant structure of an apparatus or suppression of decomposition of a material is needed. A substrate processing apparatus for performing an epitaxial film-forming process of SiC is known as a technique, for example, disclosed in Patent Document 1.

Patent Document 1 discloses a batch-type vertical substrate processing apparatus in which a plurality of substrates are stacked and processed in a vertical direction in a reaction chamber. A first gas supply nozzle and a second gas supply nozzle extend in a longitudinal direction (a vertical direction) of the reaction chamber. The first gas supply nozzle (a gas nozzle) supplies tetrachlorosilane (SiCl₄) gas, which is a silicon- and chlorine-containing gas, into the reaction chamber, and the second gas supply nozzle (a gas nozzle) supplies hydrogen (H₂) gas, which is a reducing gas, into the reaction chamber. Then, at least two kinds of reactive gases are mixed in the reaction chamber, and the mixed reactive gases flow along a surface of a wafer (a substrate). Accordingly, a SiC film is formed on the wafer through epitaxial growth.

As described above, the substrate processing apparatus disclosed in Patent Document 1 includes the first gas supply nozzle and the second gas supply nozzle such that at least two kinds of reactive gases are mixed in the reaction chamber. Accordingly, precipitation, etc. of a SiC film at an inner wall of the gas nozzle extending in the reaction chamber having a temperature of 1,500° C. to 1,800° C. or a gas supply port is suppressed.

### RELATED ART DOCUMENT

[Patent Document 1] Japanese Patent Laid-open Publication No. 2011-003885

### SUMMARY OF THE INVENTION

Meanwhile, in order to reduce costs of a substrate processing apparatus, regardless of a diameter of a wafer to be processed, components forming the substrate processing apparatus, for example, a transfer system for transferring the wafer, may be standardized as much as possible. In addition, as disclosed in Patent Document 1, in the substrate processing apparatus in which two kinds of reactive gases are mixed in the reaction chamber, in order to improve film-forming precision of the wafer, a distance between a gas supply nozzle and the wafer may be increased to substantially mix the reactive gases before arrival at the wafer. For this reason, standardization may be considered based on a substrate processing apparatus including a large-sized processing furnace corresponding to, for example, an 8-inch wafer.

However, since a size of a wafer which is actually processed is generally 2 to 4 inches, the 2- to 4-inch wafers cannot be simply processed under environments corresponding to the 8-inch wafer. For this reason, even under the environments corresponding to the 8-inch wafer, research on processing of the 2- to 4-inch wafers is also needed. Meanwhile, like the substrate processing apparatus disclosed in Patent Document 1, not limited to the substrate processing apparatus in which epitaxial film-forming of SiC is performed to mix two kinds of reactive gases in the reaction chamber, the same problem may occur even in the case in which the standardization is considered as described above.

It is an object of the present invention to provide an attachment for substrates having different diameters, that is capable of housing a downsized substrate in a substrate accommodation vessel (FOUP) constituting a transfer system corresponding to a large-sized substrate, in particular, in consideration of standardization of the transfer system, a substrate processing apparatus, and a method of manufacturing a substrate or a semiconductor device.

The above and other aspects and novel features of the present invention will be apparent from the disclosure of the specification and the accompanying drawings.

A brief description of a summary of representative embodiments of the present invention is as follows.

In order to solve the problems, an attachment for substrates having different diameters in accordance with the present invention includes: a plate-shaped member supported by a first support groove capable of supporting a substrate having a first size; and a holding member installed at the plate-shaped member and including a second support groove capable of supporting a substrate having a second size smaller than the first size.

An effect that can be obtained by a representative embodiment of the present invention will be described in detail as follows.

That is, a downsized substrate can be housed in a substrate accommodation vessel (FOUP) constituting a transfer system corresponding to a large-sized substrate.

### BRIEF DESCRIPTION OF THE DRAWINGS

FIG. 1 is a perspective view schematically showing a substrate processing apparatus employing an attachment for substrates having different diameters in accordance with the present invention;

FIG. 2 is a cross-sectional view showing an inner structure of a processing furnace;

FIG. 3 is a lateral cross-sectional view showing a lateral cross-section of the processing furnace;

FIGS. 4A and 4B are views for explaining an inner structure of a gas supply unit;

FIG. 5 is a cross-sectional view showing a peripheral structure of the processing furnace;

FIG. 6 is a block diagram for explaining a control system of the substrate processing apparatus;

FIG. 7 is a cross-sectional view showing a state in which a wafer is held on a wafer holder;

FIG. 8 is a perspective view showing the wafer and the wafer holder;

FIGS. 9A and 9B are perspective views showing an appearance of a pod;

FIG. 10 is a cross-sectional view showing a state in which an attachment for substrates having different diameters in accordance with a first embodiment is housed in a pod;

FIG. 11 is an enlarged cross-sectional view showing a portion A of FIG. 10 shown in dotted lines;

FIG. 12 is a perspective view showing the attachment for substrates having different diameters of FIG. 10;

FIGS. 13A and 13B are views for explaining an operation state of the attachment for substrates having different diameters of FIG. 10;

FIGS. 14A and 14B are views corresponding to FIG. 13 showing a structure of an attachment for substrates having different diameters in accordance with a second embodiment;

FIG. 15 is a view corresponding to FIG. 10 showing a structure of an attachment for substrates having different diameters in accordance with a third embodiment;

FIG. 16 is an enlarged cross-sectional view showing a portion B of FIG. 15 shown in dotted lines;

FIGS. 17A and 17B are views for explaining an operation state of the attachment for substrates having different diameters of FIG. 15;

FIG. 18 is a view corresponding to FIG. 10 showing a structure of an attachment for substrates having different diameters in accordance with a fourth embodiment; and

FIG. 19 is an exemplary flowchart showing a method of manufacturing a substrate or a semiconductor device in accordance with the present invention.

### DETAILED DESCRIPTION OF THE PREFERRED EMBODIMENTS

### First Embodiment

Hereinafter, a first embodiment of the present invention will be described with reference to the accompanying drawings. In the embodiment described below, a SiC epitaxial growth apparatus, which is an example of a substrate processing apparatus, is known as a batch-type vertical SiC epitaxial growth apparatus in which SiC wafers are arranged in a vertical direction (a longitudinal direction). In addition, as the batch-type vertical SiC epitaxial growth apparatus is provided, the number of SiC wafers that can be processed at once is increased to improve throughput.

<Entire Configuration>

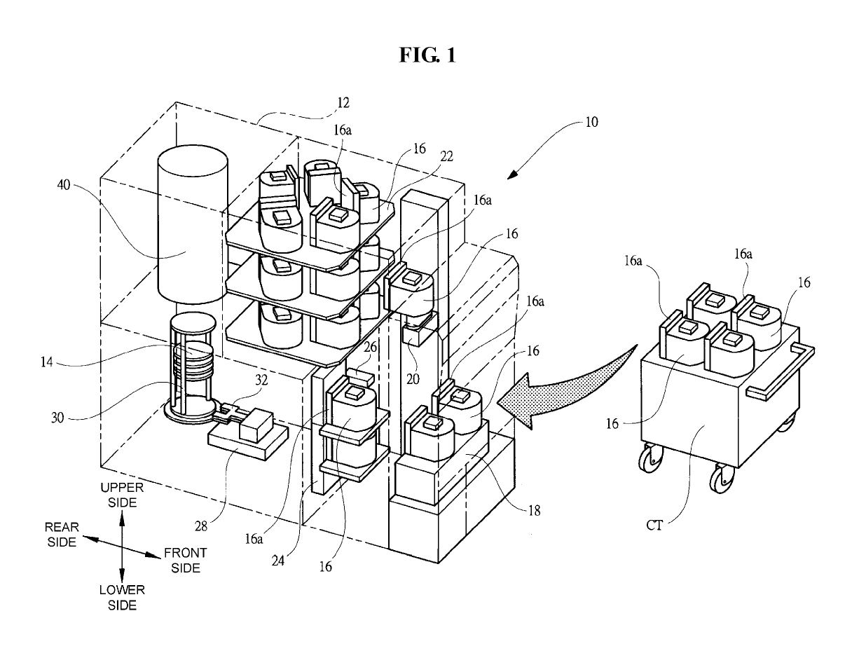

FIG. 1 is a perspective view schematically showing a substrate processing apparatus employing an attachment for substrates having different diameters in accordance with the present invention. First, a substrate processing apparatus for forming a SiC epitaxial film and a method of manufacturing a substrate to form a SiC epitaxial film, one process of manufacturing a semiconductor device, in accordance with an embodiment of the present invention will be described with reference to FIG. 1.

A semiconductor manufacturing apparatus 10, which is a substrate processing apparatus (a film forming apparatus), is a batch-type vertical annealing apparatus, and includes a housing 12 configured to accommodate a plurality of apparatuses having various functions. In the semiconductor manufacturing apparatus 10, a pod (FOUP) 16, which is a substrate accommodation vessel configured to accommodate a wafer 14, which is a substrate formed of, for example, SiC, is used as a wafer carrier.

A pod stage (a vessel introduction part) 18 configured to introduce the pod 16 into the semiconductor manufacturing apparatus 10 from an outside thereof is installed in the front of the housing 12. On the pod stage 18, a plurality of pods 16 prepared in another production line are transferred through a carrier CT pulled by an operator. For example, six wafers 14 are received in the pod 16, and set on the pod stage 18 with a cover 16a closed.

A pod transfer apparatus (a transfer mechanism) 20 is installed at a front side of the housing 12 and a rear side of the pod stage 18 to oppose the pod stage 18. The pod transfer apparatus 20 is installed between the pod stage 18 and a processing furnace 40 disposed at a rear surface side of the housing 12 to convey the pod 16 toward the processing furnace 40 from the pod stage 18. In addition, a plurality of stages (three stages in the drawing) of pod receiving shelves 22, a pod opener 24 and a substrate number detector 26 are installed at the rear surface side adjacent to the pod transfer apparatus 20. Each of the pod receiving shelves 22 is installed at an upper side of the pod opener 24 and the substrate number detector 26, and mounts and holds the plurality of pods 16 (five in the drawing) thereon.

Next, the pod transfer apparatus 20 sequentially conveys the pod 16 between the pod stage 18, each of the pod receiving shelves 22 and the pod opener 24, and the pod opener 24 opens the cover 16a of the pod 16. Then, the substrate number detector 26 installed near the pod opener 24 detects the number of wafers 14 in the pod 16 with the cover 16a open.

In addition, a substrate transfer apparatus 28 and a boat 30, which is a substrate holder, are installed in the housing 12. The substrate transfer apparatus 28 includes, for example, six arms (tweezers) 32, and each of the arms 32 is configured to be raised or lowered with rotation by a drive means (not shown) to extract the six wafers 14 from the pod 16 at once. Then, as each arm 32 is reversely moved toward the rear surface side from the front surface side, the wafers 14 may be transferred by six to the boat 30 from the pod 16 disposed at a position of the pod opener 24.

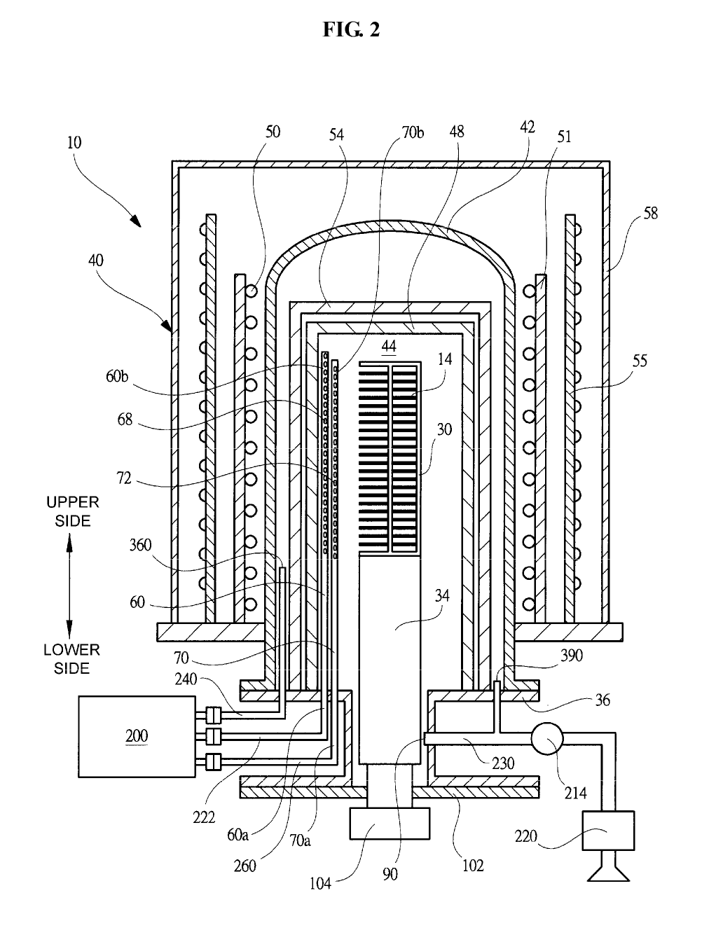

The boat 30 is formed of a heat-resistant material such as carbon graphite or SiC in a predetermined shape, and is configured to concentrically stack and hold the plurality of wafers 14 in a horizontal posture in a longitudinal direction thereof. Meanwhile, a boat insulating part 34, which is an insulating member formed of a heat-resistant material such as quartz or SiC in a cylindrical column shape, is installed under the boat 30 so that heat from a heater 48 cannot be easily transferred to a lower side of the processing furnace 40 (see FIG. 2).

The processing furnace 40 is installed at an upper side of a rear surface side in the housing 12. The boat 30 on which the plurality of wafers 14 are charged is loaded into the processing furnace 40, and thus, the plurality of stacked wafers 14 may be annealed (batch processed) at once.

<Configuration of Processing Furnace>

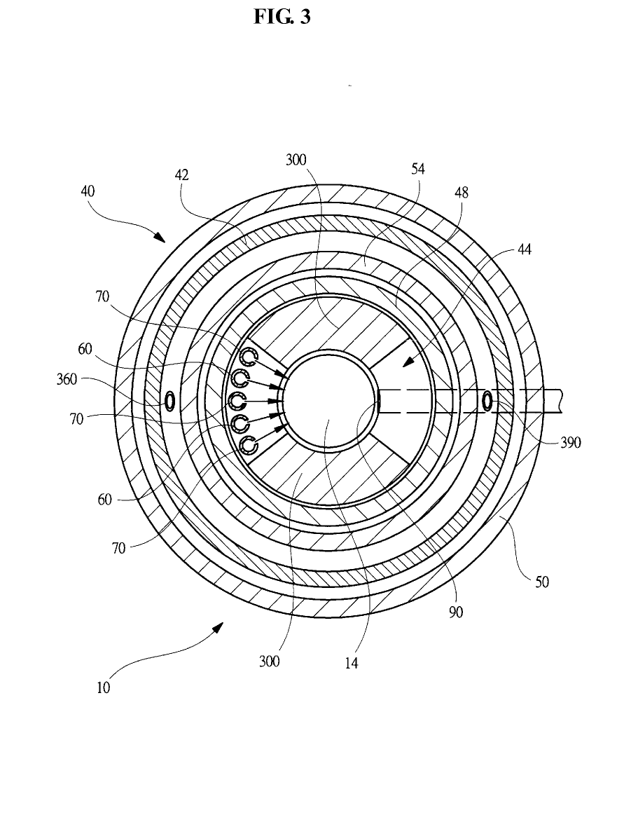

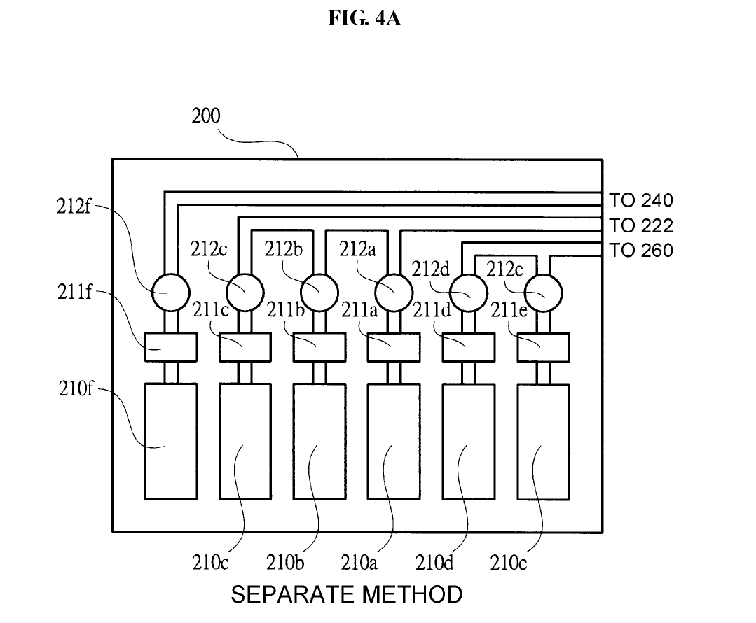

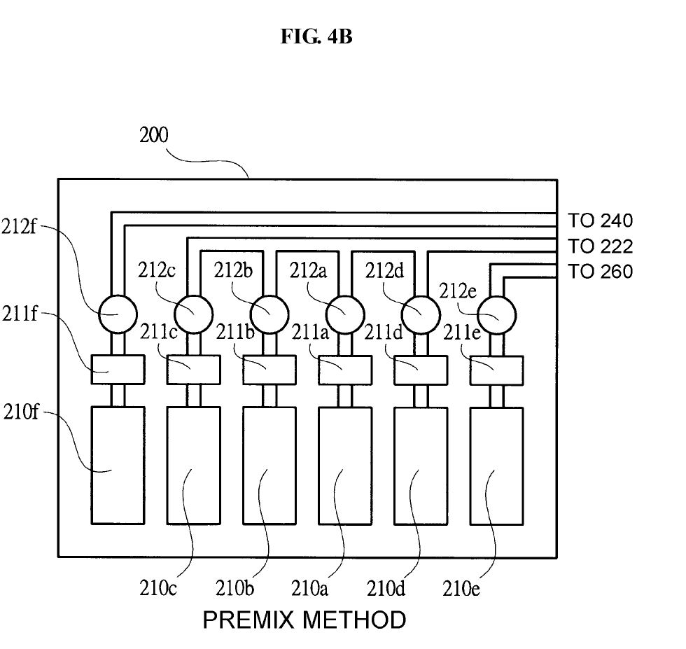

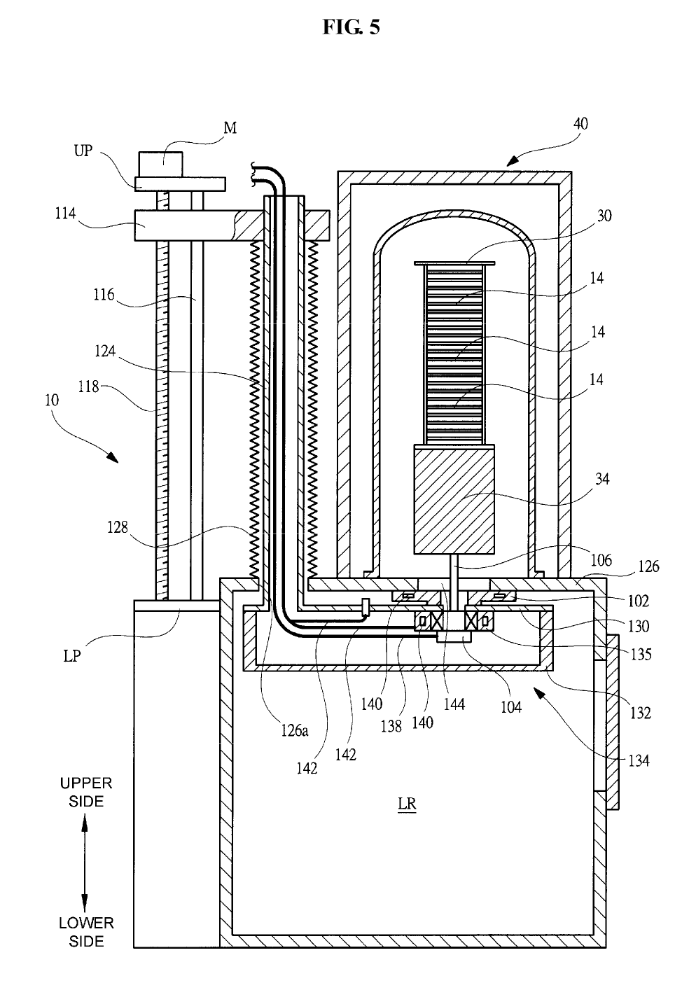

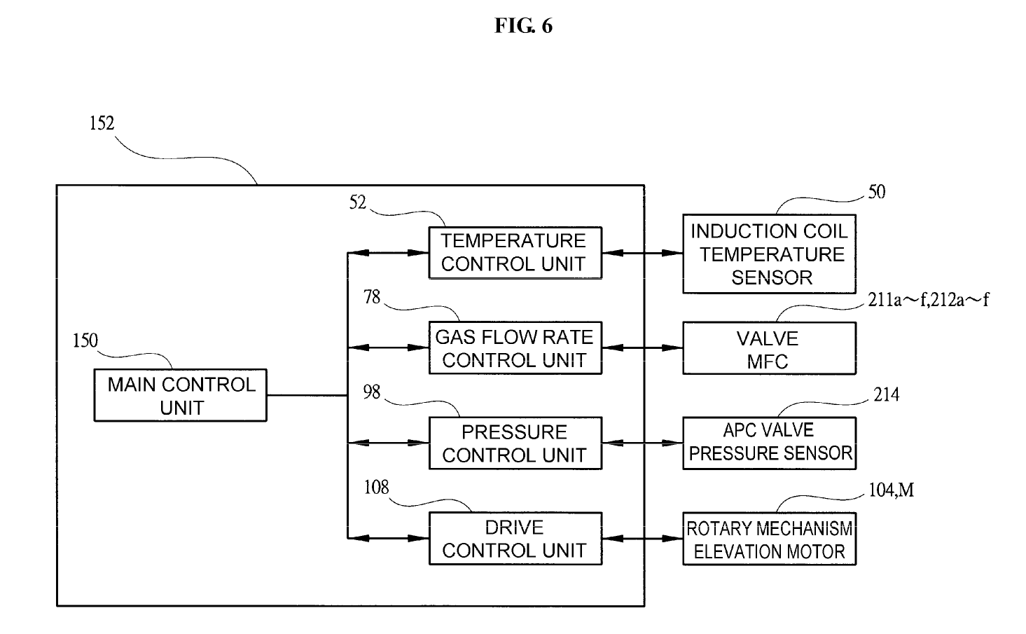

FIG. 2 is a cross-sectional view showing an inner structure of a processing furnace, FIG. 3 is a lateral cross-sectional view showing a lateral cross-section of the processing furnace, FIGS. 4A and 4B are views for explaining an inner structure of a gas supply unit, FIG. 5 is a cross-sectional view showing a peripheral structure of the processing furnace, and FIG. 6 is a block diagram for explaining a control system of the substrate processing apparatus. Hereinafter, the processing furnace 40 of the semiconductor manufacturing apparatus 10 for forming a SiC epitaxial film will be described with reference to FIGS. 2 to 6.

The processing furnace 40 includes a first gas supply nozzle 60 having a first gas supply port 68, a second gas supply nozzle 70 having a second gas supply port 72, and a first gas exhaust port 90 configured to exhaust reactive gases from the gas supply nozzles 60 and 70 to the outside. In addition, the processing furnace 40 further includes a third gas supply port 360 configured to supply an inert gas and a second gas exhaust port 390 configured to exhaust the inert gas to the outside.

The processing furnace 40 includes a reaction tube 42. The reaction tube 42 is formed of a heat-resistant material such as quartz or SiC, and has a cylindrical shape with an upper side closed and a lower side opened. A manifold 36 is disposed at an opening side (a lower side) of the reaction tube 42 to form a concentric relationship with the reaction tube 42. The manifold 36 is formed of a material such as stainless steel, and has a cylindrical shape with upper and lower sides opened. The manifold 36 supports the reaction tube 42, and an O-ring (not shown), which is a seal member, is installed between the manifold 36 and the reaction tube 42. Accordingly, a leakage of a reactive gas filled in the reaction tube 42 and the manifold 36 to the outside is prevented.

The manifold 36 is supported by a holding body (not shown) installed at a lower side thereof, and thus, the reaction tube 42 is vertically installed with respect to the ground (not shown). Here, the reaction tube 42 and the manifold 36 constitute a reaction vessel.

The processing furnace 40 includes the heater 48. The heater 48 has a bottomed cylindrical shape with an upper side closed and a lower side opened. The heater 48 is installed in the reaction tube 42, and a reaction chamber 44 is formed in the heater 48. The boat 30 on which the wafer 14 formed of SiC is held is received in the reaction chamber 44.

The processing furnace 40 includes an induction coil 50 acting as a magnetic field generating part. The induction coil 50 is fixed to an inner circumference side of a cylindrical support member 51 in a spiral shape, and the induction coil 50 is electrically connected to an external power supply (not shown). As the induction coil 50 is electrically connected, the induction coil 50 generates a magnetic field and thus the heater 48 is induction-heated. As described above, as the heater 48 generates heat through induction heating, the inside of the reaction chamber 44 is heated.

A temperature sensor (not shown), which is a temperature detector configured to detect a temperature in the reaction chamber 44, is installed near the heater 48, and the temperature sensor and the induction coil 50 are electrically connected to a temperature control unit 52 of a controller 152 (see FIG. 6). The temperature control unit 52 adjusts (controls) a conduction state to the induction coil 50 at a predetermined timing such that the temperature in the reaction chamber 44 reaches a desired temperature distribution based on temperature information detected by the temperature sensor.

An insulating material 54 formed of, for example, carbon felt, which cannot be easily induction-heated, is installed between the reaction tube 42 and the heater 48. The insulating material 54 is formed in a bottomed cylindrical shape with an upper side closed and a lower side opened, similar to the reaction tube 42 and the heater 48. As described above, as the insulating material 54 is installed, transfer of heat from the heater 48 to the reaction tube 42 or the outside of the reaction tube 42 is suppressed.

In addition, in order to suppress transfer of the heat in the reaction chamber 44 to the outside, for example, an outer insulating wall 55 having a water cooling structure is installed at an outer circumference side of the induction coil 50. The outer insulating wall 55 has a cylindrical shape and is disposed to surround the reaction chamber 44 (the support member 51). In addition, a magnetic seal 58 configured to prevent leakage of the magnetic field generated due to conduction to the induction coil 50 to the outside is installed at an outer circumference side of the outer insulating wall 55. The magnetic seal 58 has a bottomed cylindrical shape with an upper side closed and a lower side opened.

The first gas supply nozzle 60 including the first gas supply port 68 is installed between an inner circumference side of the heater 48 and an outer circumference side of the wafer 14. In addition, the second gas supply nozzle 70 including the second gas supply port 72 is installed between the inner circumference side of the heater 48 and the outer circumference side of the wafer 14. The first gas supply nozzle 60 and the second gas supply nozzle 70 are installed at predetermined intervals in a circumferential direction of each of the wafers 14, and the gas supply ports 68 and 72 of the gas supply nozzles 60 and 70 are directed to the wafers 14. Further, the first gas exhaust port 90 is also opened between the inner circumference side of the heater 48 and the outer circumference side of the wafer 14. That is, the gas support ports 68 and 72 and the first gas exhaust port 90 face the reaction chamber 44. Further, the third gas supply port 360 and the second gas exhaust port 390 are installed between an inner circumference side of the reaction tube 42 and an outer circumference side of the insulating material 54.

Here, as shown in FIG. 2, while at least one first gas supply nozzle 60 and at least one second gas supply nozzle 70 may be installed, as shown in FIG. 3, two first gas supply nozzles 60 and three second gas supply nozzles 70 may be installed. In this case, the two first gas supply nozzles 60 are alternately disposed between the three second gas supply nozzles 70 in a circumferential direction of the wafer 14. Accordingly, when different kinds of reactive gases are supplied from the first gas supply nozzles 60 and the second gas supply nozzles 70, the reactive gases can be mixed to obtain good efficiency in the reaction chamber 44. In addition, as the sum of the first gas supply nozzles 60 and the second gas supply nozzles 70 is an odd number, the reactive gases can be supplied in a well-balanced manner from both sides (upper and lower sides of FIG. 3) with the middle gas supply nozzle as a center thereof. Accordingly, the reactive gases can be uniformly supplied to a film-forming surface of the wafer 14 to enable improvement in film-forming precision. Further, the kinds of the reactive gases supplied from the first gas supply nozzles 60 and the second gas supply nozzles 70 will be described below.

As shown in FIG. 2, the first gas supply nozzle 60 is formed of a heat resistant material such as carbon graphite in a hollow pipe shape and includes a proximal end 60a and a front end 60b. The proximal end 60a of the first gas supply nozzle 60 is installed at an opening side of the reaction vessel constituted by the reaction tube 42 and the manifold 36, i.e., a side of the manifold 36, and passes through the manifold 36 to be fixed to the manifold 36. The first gas supply nozzle 60 is installed to extend in the reaction chamber 44 in a longitudinal direction thereof, i.e., extend in a stack direction of the wafers 14, and the front end 60b of the first gas supply nozzle 60 is installed at a bottomed side (an upper side) of the reaction tube 42.

A plurality of first gas supply ports 68 configured to supply reactive gases to the plurality of wafers 14 and arranged from the proximal end 60a to the front end 60b are installed at a side of the front end 60b in a longitudinal direction of the first gas supply nozzle 60, i.e., positions corresponding to the wafers 14 between the proximal end 60a and the front end 60b of the first gas supply nozzle 60. The first gas supply ports 68 are installed at predetermined intervals, and thus, the reactive gases can be uniformly supplied to the plurality of wafers 14, respectively. In addition, the proximal end 60a of the first gas supply nozzle 60 is connected to a gas supply unit 200 via a first gas line 222.

The second gas supply nozzle 70 is formed of a heat resistant material such as carbon graphite in a hollow pipe shape, and includes a proximal end 70a and a front end 70b. The proximal end 70a of the second gas supply nozzle 70 is installed at an opening side of the reactive vessel constituted by the reaction tube 42 and the manifold 36, i.e., a side of the manifold 36, and passes through the manifold 36 to be fixed to the manifold 36. The second gas supply nozzle 70 is installed in the reaction chamber 44 to extend in a longitudinal direction thereof, and the front end 70b of the second gas supply nozzle 70 is installed at a bottom side of the reaction tube 42.

A plurality of second gas supply ports 72 configured to supply reactive gases to the plurality of wafers 14 and arranged from the proximal end 70a to the front end 70b are installed at a side of the front end 70b in a longitudinal direction of the second gas supply nozzle 70, i.e., positions corresponding to the wafers 14 between the proximal end 70a and the front end 70b of the second gas supply nozzle 70. The second gas supply ports 72 are installed at predetermined intervals, and thus, the reactive gases can be uniformly supplied to the plurality of wafers 14, respectively. In addition, the proximal end 70a of the second gas supply nozzle 70 is connected to the gas supply unit 200 via a second gas line 260.

Here, as shown in FIG. 3, in the reaction chamber 44, structures 300 having an arc-shaped cross-section and extending in the longitudinal direction of the reaction chamber 44 may be installed between the gas supply nozzles 60 and 70 and the first gas supply port 90 and between the heater 48 and the wafers 14 to fill spaces corresponding thereto. For example, as shown in FIG. 3, as the structures 300 are installed at opposite positions, the reactive gases supplied from the gas supply nozzles 60 and 70 can be prevented from flowing along the inner wall of the heater 48 and bypassing the wafer 14. In consideration of heat resistance and generation of particles, the structures 300 may be formed of carbon graphite, etc.

As shown in FIG. 2, the first gas exhaust port 90 is installed under the boat 30 at an opposite position of the gas supply ports 68 and 72 with the boat 30 interposed therebetween, and a gas exhaust pipe 230 connected to the first gas exhaust port 90 passes through the manifold 36 to be fixed thereto. A pressure sensor (not shown), which is a pressure detector, is installed at a downstream side of the gas exhaust pipe 230, and a vacuum exhaust apparatus 220 such as a vacuum pump is connected to an upstream side thereof via an automatic pressure controller (APC) valve 214, which is a pressure regulator. A pressure control unit 98 (see FIG. 6) of the controller 152 is electrically connected to the pressure sensor and the APC valve 214. The pressure control unit 98 adjusts (controls) an opening degree of the APC valve 214 at a predetermined timing based on the pressure detected by the pressure sensor, and further, adjusts a pressure in the processing furnace 40 to a predetermined pressure.

As described above, as the first gas exhaust port 90 is disposed at an opposite position of the gas supply ports 68 and 72, the reactive gases supplied from the gas supply ports 68 and 72 can be flowed from a side of the wafer 14 in a horizontal direction to be fully and widely spread onto the film-forming surface of the wafer 14, and then, exhausted from the first gas exhaust port 90. Accordingly, the entire film-forming surface of the wafer 14 can be effectively and uniformly exposed to the reactive gases to improve film-forming precision.

The third gas supply port 360 is disposed adjacent to the gas supply ports 68 and 72 between the reaction tube 42 and the insulating material 54. The third gas supply port 360 is installed at one end side of a third gas line 240 fixed to the manifold 36 through the manifold 36, and the other end side of the third gas line 240 is connected to the gas supply unit 200. In addition, the second gas exhaust port 390 is disposed adjacent to the first gas exhaust port 90 between the reaction tube 42 and the insulating material 54, i.e., an opposite position of the third gas supply port 360 with the insulating material 54 interposed therebetween, and the second gas exhaust port 390 is connected to the gas exhaust pipe 230.

As shown in FIG. 4, the third gas line 240 is connected to a fourth gas supply source 210f via a valve 212f and a mass flow controller (MFC) 211f. For example, Ar gas, which is a rare gas acting as an inert gas, is supplied from the fourth gas supply source 210f to prevent the reactive gas contributing to growth of a SiC epitaxial film from entering between the reaction tube 42 and the insulating material 54. Accordingly, since there is no unnecessary byproduct stuck to an inner wall of the reaction tube 42 or an outer wall of the insulating material 54, a maintenance period of the apparatus can be increased. In addition, the inert gas (Ar gas, etc.) supplied between the reaction tube 42 and the insulating material 54 is exhausted to the outside from the vacuum exhaust apparatus 200 via the second gas exhaust port 390, the gas exhaust pipe 230 and the APC valve 214.

<Configuration of Reactive Gas Supply System>

Hereinafter, a first gas supply system and a second gas supply system will be described with reference to FIG. 4. FIG. 4A shows a separate method of supplying a silicon atom-containing gas and a carbon atom-containing gas through different gas supply nozzles, and FIG. 4B shows a premix method of supplying a silicon atom-containing gas and a carbon atom-containing gas through the same gas supply nozzle.

First, the separate method will be described. As shown in FIG. 4A, in the separate method, the first gas line 222 is connected to a first gas supply source 210a, a second gas supply source 210b and a third gas supply source 210c via valves 212a, 212b and 212c and MFCs (flow rate control means) 211a, 211b and 211c. SiH₄ gas is supplied from the first gas supply source 210a, HCl gas is supplied from the second gas supply source 210b, and an inert gas is supplied from the third gas supply source 210c.

Accordingly, supply flow rates, concentrations, partial pressures and supply timings of the SiH₄ gas, the HCl gas and the inert gas into the reaction chamber 44 can be controlled. The valves 212a to 212c and the MFCs 211a to 211c are electrically connected to a gas flow rate control unit 78 (see FIG. 6) of the controller 152. The gas flow rate control unit 78 is configured to control a flow rate of gases to be supplied to predetermined flow rates at predetermined timings. Here, the first gas supply system is constituted by the gas supply sources 210a to 210c, which supply SiH₄ gas (a film-forming gas), HCl gas (an etching gas), and an inert gas, respectively, the valves 212a to 212c, the MFCs 211a to 211c, the first gas line 222, the first gas supply nozzle 60 and the first gas supply port 68.

The second gas line 260 is connected to a fifth gas supply source 210d and a sixth gas supply source 210e via valves 212d and 212e and MFCs 211d to 211e. A carbon atom-containing gas such as C₃H₈ gas (a film-forming gas) is supplied from the fifth gas supply source 210d, and a reducing gas such as H₂ gas is supplied from the sixth gas supply source 210e.

Accordingly, supply flow rates, concentrations, partial pressures, and supply timings of the C₃H₈ gas and the H₂ gas into the reaction chamber 44 can be controlled. The valves 212d and 212e and the MFCs 211d and 211e are electrically connected to the gas flow rate control unit 78 (see FIG. 6) of the controller 152. The gas flow rate control unit 78 is configured to control flow rates of gases to be supplied to predetermined flow rates at predetermined timings. Here, the second gas supply system is constituted by the gas supply sources 210d and 210e, which supply the C₃H₈ gas and the H₂ gas, respectively, the valves 212d and 212e, the MFCs 211d and 211e, the second gas line 260, the second gas supply nozzle 70 and the second gas supply port 72.

In the separate method, as the silicon atom-containing gas and the carbon atom-containing gas are supplied from different gas supply nozzles, film-forming (accumulation) of a SiC film in the gas supply nozzle is prevented. In addition, when concentrations and flow velocities of the silicon atom-containing gas and the carbon atom-containing gas are adjusted, appropriate carrier gases may be supplied, respectively.

Further, in order to efficiently use the silicon atom-containing gas, H₂ gas is used as a reducing gas, and the H₂ gas is supplied from the second gas supply nozzle 70 with the carbon atom-containing gas. Accordingly, in the reaction chamber 44, the H₂ gas and the carbon atom-containing gas are mixed with the silicon atom-containing gas to reduce an amount of H₂ gas, and thus, decomposition of the silicon atom-containing gas is suppressed in comparison with the film forming. As a result, the film-forming (accumulation) of the SiC film in the first gas supply nozzle 60 is suppressed. In this case, the H₂ gas is used as a carrier gas of the carbon atom-containing gas. In addition, an inert gas (in particular, a rare gas) such as Ar gas may be used as a carrier gas of the silicon atom-containing gas to suppress accumulation of the SiC film.

In addition, HCl gas is supplied as a chlorine atom-containing gas from the first gas supply nozzle 60. Accordingly, even when the silicon atom-containing gas is pyrolyzed to be in a state in which the Si film can be accumulated in the first gas supply nozzle 60, an etching mode is made by the HCl gas, and thus, the film forming (accumulation) of the Si film in the first gas supply nozzle 60 is suppressed. Further, since the HCl gas has an effect of etching the accumulated Si film, blocking of the first gas supply port 68 can be effectively suppressed.

Hereinafter, the premix method shown in FIG. 4B will be described. The premix method is distinguished from the separate method in that a carbon atom-containing gas supply source 210d is connected to the first gas line 222 via the MFC 211d and the valve 212d. Accordingly, the silicon atom-containing gas and the carbon atom-containing gas may be premixed in the first gas line 222. As a result, mixing efficiency of the reactive gas can be increased in comparison with the separate method, and thus, film-forming time can be reduced.

In this case, since the H₂ gas may be solely supplied from the second gas supply nozzle 70 via the second gas line 260, a ratio (Cl/H) of the HCl gas and the H₂ gas may be increased, and further, an etching effect in the first gas supply nozzle 60 may be increased, suppressing reaction of the silicon atom-containing gas. As described above, even in the premix method, the film forming (accumulation) of the SiC film in the first gas supply nozzle 60 may be suppressed to some extent.

In addition, as described above, while the HCl gas is used as a chlorine atom-containing gas (an etching gas) used when the SiC epitaxial film is formed, Cl gas (chlorine gas), etc. may be used but is not limited thereto.

Further, as described above, while the silicon atom-containing gas and the chlorine atom-containing gas are separately supplied when the SiC epitaxial film is formed, a gas containing Si atoms and Cl atoms such as tetrachlorosilane (SiCl₄) gas, trichlorosilane (SiHCl₃) gas, and dichlorosilane (SiH₂Cl₂) gas may be supplied, but is not limited thereto. The gas containing the Si atoms and the Cl atoms may be a silicon atom-containing gas or a mixed gas of a silicon atom-containing gas and a chlorine atom-containing gas. In particular, since SiCl₄ gas is pyrolyzed at a relatively high temperature, consumption of the Si atoms in the first gas supply nozzle 60 may be preferably suppressed.

Furthermore, as described above, while the C₃H₈ gas is used as a carbon atom-containing gas, ethylene (C₂H₄) gas, acetylene (C₂H₂) gas, and so on, may be used.

In addition, as described above, while the H₂ gas is used as a reducing gas, another hydrogen atom-containing gas may be used, but is not limited thereto. Further, the carrier gas may use at least one of rare gases such as Ar (argon) gas, He (helium) gas, Ne (neon) gas, Kr (krypton) gas, and Xe (xenon) gas, or may use an arbitrarily mixed gas of the rare gases.

<Configuration of Periphery of Processing Furnace>

Hereinafter, the processing furnace 40 and its peripheral components will be described with reference to FIG. 5. A seal cap (a furnace port cover) 102 configured to hermetically seal a furnace port 144, which is an opening of the processing furnace 40, is installed under the processing furnace 40. The seal cap 102 is formed of a metal material such as stainless steel in a substantial disc shape. An O-ring (not shown), which is a seal member configured to seal a gap between the seal cap 102 and a top plate 126 of the processing furnace 40, is installed between the seal cap 102 and the top plate 126, hermetically holding the processing furnace 40.

A rotary mechanism 104 is installed at the seal cap 102, and a rotary shaft 106 of the rotary mechanism 104 is connected to the boat insulating part 34 through the seal cap 102. In addition, as the rotary mechanism 104 is rotated, the boat 30 is rotated in the processing furnace 40 via the rotary shaft 106, and thus, the wafer 14 is also rotated.

The seal cap 102 is configured to be raised and lowered in a vertical direction (upward and downward) by an elevation motor (an elevation mechanism) M installed outside the processing furnace 40 so that the boat 30 can be loaded into and unloaded from the processing furnace 40. A drive control unit 108 (see FIG. 6) of the controller 152 is electrically connected to the rotary mechanism 104 and the elevation motor M. The drive control unit 108 is configured to control the rotary mechanism 104 and the elevation motor M to perform a predetermined operation at a predetermined timing.

A load lock chamber LR, which is a preliminary chamber, is installed under the processing furnace 40, and a lower plate LP is installed outside the load lock chamber LR. A proximal end of a guide shaft 116 configured to slidably support an elevation frame 114 is fixed to the lower plate LP, and a proximal end of a ball screw 118 threadedly engaged with the elevation frame 114 is rotatably supported by the lower plate LP. In addition, an upper plate UP is mounted on a front end of the guide shaft 116 and a front end of the ball screw 118. The ball screw 118 is rotated by the elevation motor M mounted on the upper plate, and the elevation frame 114 is raised or lowered by rotation of the ball screw 118.

An elevation shaft 124 having a hollow pipe shape is fixed to the elevation frame 114 to be vertically hung, and a connecting part of the elevation frame 114 and the elevation shaft 124 is hermetically sealed. Accordingly, the elevation shaft 124 is raised or lowered with the elevation frame 114. The elevation shaft 124 passes through a through-hole 126a formed in the top plate 126 of an upper side of the load lock chamber LR with a predetermined gap. That is, when the elevation shaft 124 is elevated, the elevation shaft 124 does not contact the top plate 126.

A bellows (a hollow flexible body) 128 having flexibility to cover the elevation shaft 124 is installed between the load lock chamber LR and the elevation frame 114, and the load lock chamber LR is hermetically held by the bellows 128. In addition, the bellows 128 has a sufficient elongation to correspond to an elevation length of the elevation frame 114, and an inner diameter sufficiently larger than an outer diameter of the elevation shaft 124. Accordingly, the bellows 128 can be smoothly expanded and contracted without contacting the elevation shaft 124 upon expansion and contraction.

An elevation plate 130 is horizontally fixed to a lower side of the elevation shaft 124, and a drive part cover 132 is hermetically attached to a lower side of the elevation plate 130 via a seal member (not shown) such as an O-ring. The elevation plate 130 and the drive part cover 132 constitute a drive part receiving case 134, and thus, an atmosphere in the drive part receiving case 134 is isolated from an atmosphere in the load lock chamber LR.

The rotary mechanism 104 configured to rotate the boat 30 is installed in the drive part receiving case 134, and a periphery of the rotary mechanism 104 is cooled by a cooling mechanism 135 having a water cooling structure.

A power cable 138 is electrically connected to the rotary mechanism 104, and the power cable 138 is guided to the rotary mechanism 104 from an upper side of the elevation shaft 124 through a hollow portion. In addition, cooling water flow paths 140 are formed at the cooling mechanism 135 and the seal cap 102, respectively, and cooling water pipes 142 are connected to the cooling water flow paths 140, respectively. The cooling water pipes 142 are guided to the cooling flow paths 140 from the upper side of the elevation shaft 124 through the hollow portion, respectively.

As the elevation motor M is rotated by the drive control unit 108 of the controller 152, the ball screw 118 is rotated and thus the elevation frame 114 and the elevation shaft 124 are raised or lowered, and further, the drive part receiving case 134 is raised or lowered. Then, as the drive part receiving case 134 is raised, the seal cap 102 hermetically installed at the elevation plate 130 closes the furnace port 144, which is an opening of the processing furnace 40, and thus, the wafer 14 is in a state in which it can be annealed. In addition, as the drive part receiving case 134 is lowered, the boat 30 is lowered with the seal cap 102, and the wafer 14 is in a state in which it can be unloaded to the outside of the processing furnace 40.

As shown in FIG. 6, the controller 152 configured to control the semiconductor manufacturing apparatus 10 for forming the SiC epitaxial film includes the temperature control unit 52, the gas flow rate control unit 78, the pressure control unit 98 and the drive control unit 108. The temperature control unit 52, the gas flow rate control unit 78, the pressure control unit 98 and the drive control unit 108 constitute an operation part and an input/output part, and are electrically connected to a main control unit 150 configured to control the entire semiconductor manufacturing apparatus 10.

<Stacking Structure of Wafers>

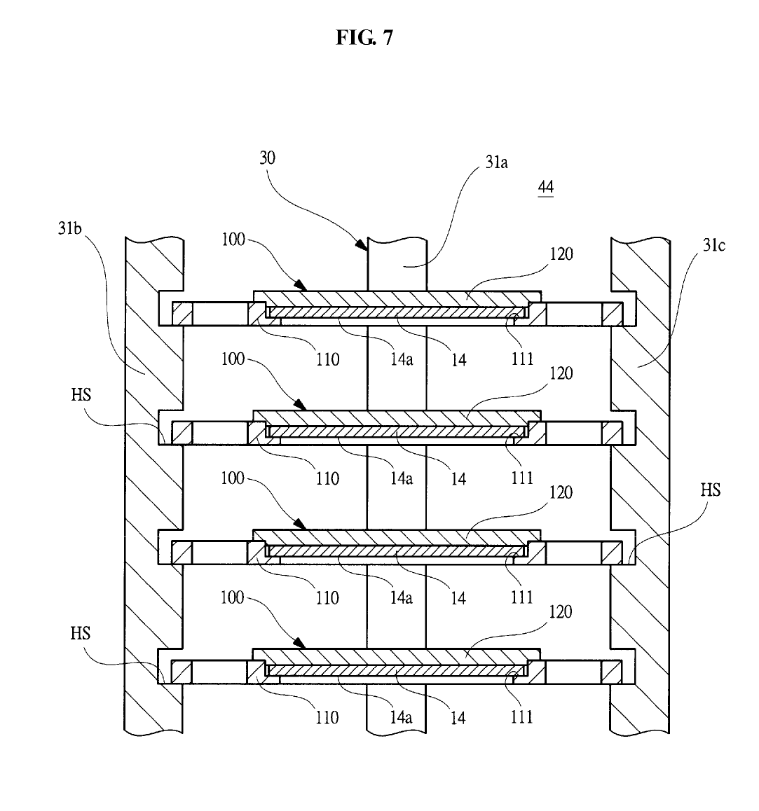

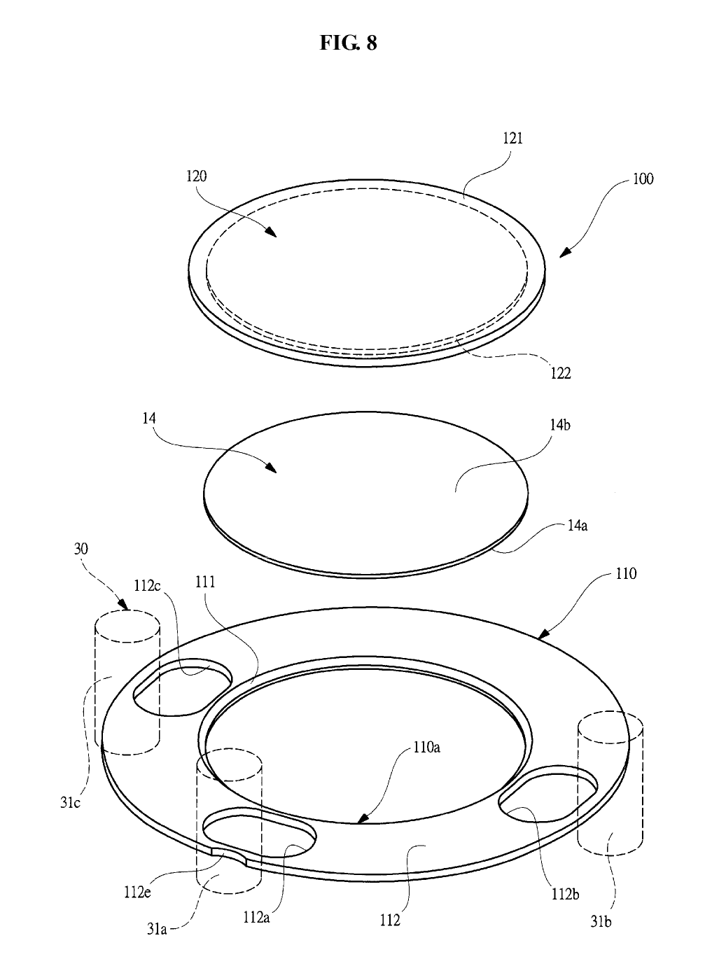

Hereinafter, a stacking structure of the wafer 14 onto the boat 30 will be described in detail with reference to the drawings. FIG. 7 is a cross-sectional view showing a state in which a wafer is held on a wafer holder, and FIG. 8 is a perspective view showing the wafer and the wafer holder.

The boat 30 includes three boat columns configured to support the plurality of wafers 14 in a horizontal posture, i.e., a first boat column 31a, a second boat column 31b and a third boat column 31c. Each of the boat columns 31a to 31c is formed of a heat resistant material such as SiC, and the boat columns are integrally configured via an upper plate member and a lower plate member (neither is shown).

The boat columns 31a to 31c have the same shape, and in a state in which the boat 30 is assembled, a plurality of holder supports HS formed with cutout portions are formed at opposite sides of the boat columns 31a to 31c. The holder supports HS separately hold outer circumferences of wafer holders 100 on which the wafers 14 are mounted, and are installed at predetermined intervals in a longitudinal direction of the boat columns 31a to 31c, for example, to 30 stages. That is, the boat 30 is configured to concentrically stack and hold 30 wafers 14 in a horizontal posture in a longitudinal direction via the wafer holders 100.

The first boat column 31a and the second boat column 31b are disposed at a 90° interval in a circumferential direction of the wafer 14. In addition, the second boat column 31b and the third boat column 31c are disposed at a 180° interval in the circumferential direction of the wafer 14. That is, the gap between the first boat column 31a and the second boat column 31b is smaller than that between the second boat column 31b and the third boat column 31c. In addition, the first boat column 31a and the third boat column 31c are disposed at a 90° interval in the circumferential direction of the wafer 14, similar to a relationship between the first boat column 31a and the second boat column 31b. The widest opening of the intervals between the boat columns 31a to 31c, i.e., the opening between the second boat column 31b and the third boat column 31c becomes an opening (a loading/unloading part) configured to transfer the wafer holders 100 holding the wafers 14.

Each of the wafer holders 100, on which the wafers 14 are mounted, has a disc shape, as shown in FIG. 8, and includes a holder base (a substrate holder) 110 having an annular shape, and a holder cover 120 having a disc shape. Here, the holder base 110 and the holder cover 120 are formed of a heat resistant material such as SiC.

An outer diameter of the holder base 110 constituting the wafer holder 100 is set to a larger dimension than an outer dimension of the wafer 14. The holder base 110 has a through-hole 110a formed at a center thereof and passing through the holder base 110 in an axial direction, and an annular step portion 111 is formed at an inner circumference of the through-hole 110a. The annular step portion 111 holds the wafer 14.

As described above, as the wafer 14 is held on the annular step portion 111 of the holder base 110, the wafer 14 can be precisely positioned (mounted) on a center portion of the holder base 110. In addition, as shown in FIG. 7, the wafer 14 may be spaced apart from the boat columns 31a to 31c. Further, as the wafer 14 is held on the annular step portion 111, a lower surface 14a of the wafer 14, which becomes a film-forming surface, may be exposed to an atmosphere in the reaction chamber 44.

In a state in which the wafer holder 100 is transferred to the boat 30, three communication holes, i.e., a first communication hole 112a, a second communication hole 112b and a third communication hole 112c are installed at portions of a main body 112 of the holder base 110 corresponding to the boat columns 31a to 31c in a thickness direction of the main body 112, i.e., the axial direction of the wafer holder 100 to penetrate the main body 112.

In addition, a notch portion 112e having an arc shape is formed adjacent to the first communication hole 112a in the circumferential direction of the main body 112. The notch portion 112e contacts a holder position determining rod 406 of an attachment 400 for substrates having different diameters, and thus, the wafer holder 100 can be precisely positioned with respect to the attachment 400 for substrates having different diameters. Accordingly, when the arm 32 (see FIG. 1) of the substrate transfer apparatus 28 is operated to transfer the wafer holder 100 (the wafer 14) from the attachment 400 for substrates having different diameters to the boat 30, the communication holes 112a to 112c can be securely opposite to the boat columns 31a to 31c with no offset.

The communication holes 112a to 112c are installed in consideration of consumption of a reactive gas by the boat columns 31a to 31c, respectively. That is, when the reactive gas is supplied to the wafer 14, the reactive gas is also supplied to the boat columns 31a to 31c according to rotation of the boat 30 to form films on the boat columns 31a to 31c. Accordingly, in order to suppress consumption of the reactive gas before arrival at the wafer 14, the communication holes 112a to 112c are formed as spaces in which the reactive gas is not consumed. As a result, the film can be formed on the lower surface 14a of the wafer 14 to a uniform thickness.

The holder cover 120 includes a large diameter main body 121 and a small diameter mating part 122 so that the small diameter mating part 122 is inserted into the annular step portion 111 of the holder base 110 to be mounted thereon. Accordingly, shaking of the holder cover 120 with respect to the holder base 110 is suppressed. The small diameter mating part 122 contacts an upper surface (no film-forming surface) 14b of the wafer 14 opposite to the lower surface 14a, which is a film-forming surface, via the wafer 14 interposed between the annular step portion 111 and the small diameter mating part 122. As described above, the holder cover 120 covers the upper surface 14b of the wafer 14 to prevent a film from being formed on the upper surface 14b and protect the wafer 14 from particles (fine dust) dropped from above the wafer 14.

<Structure of Pod and Attachment for Substrates Having Different Diameters>

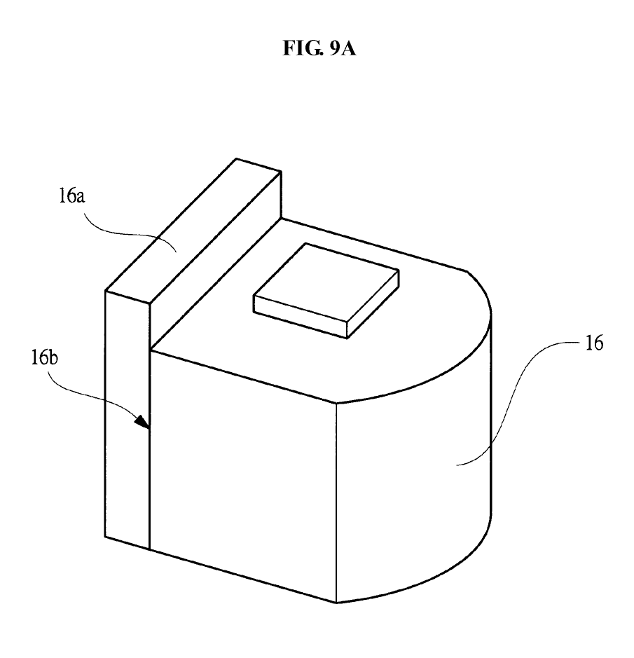

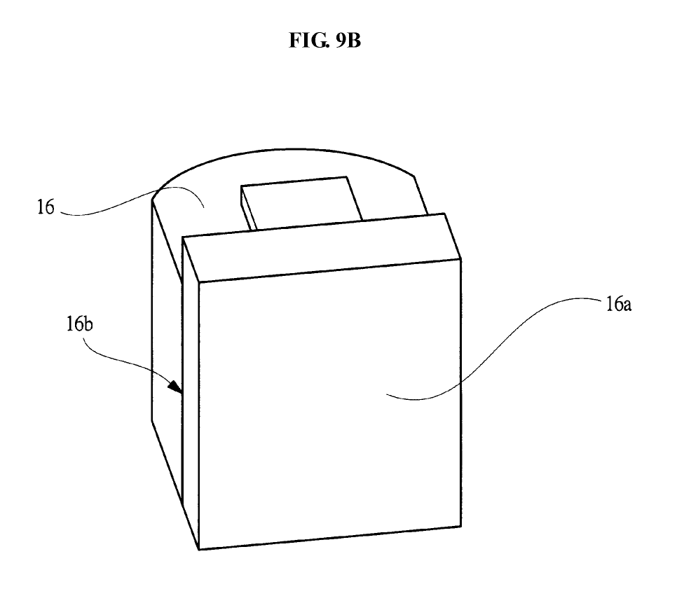

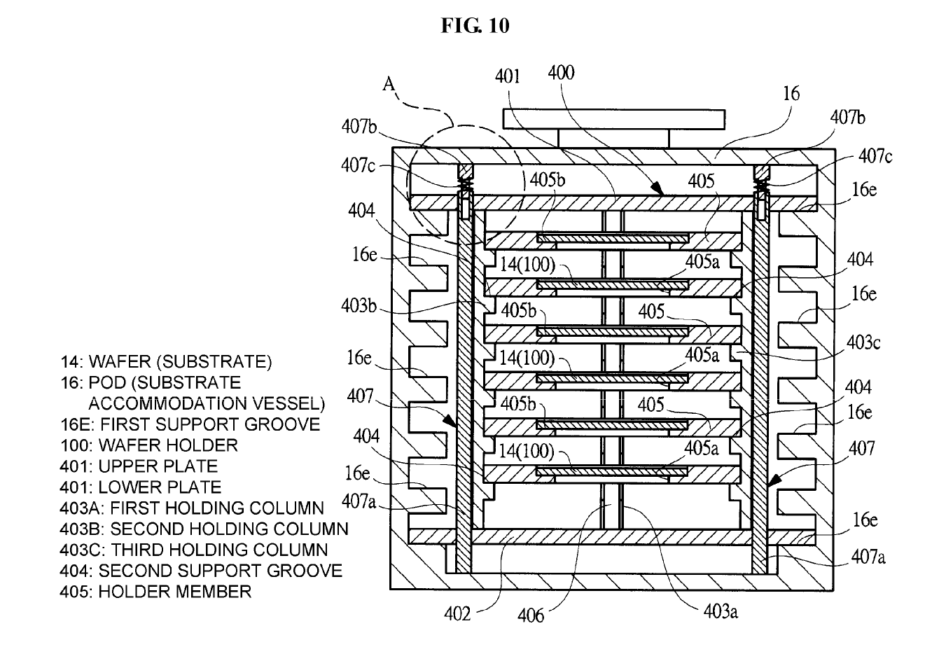

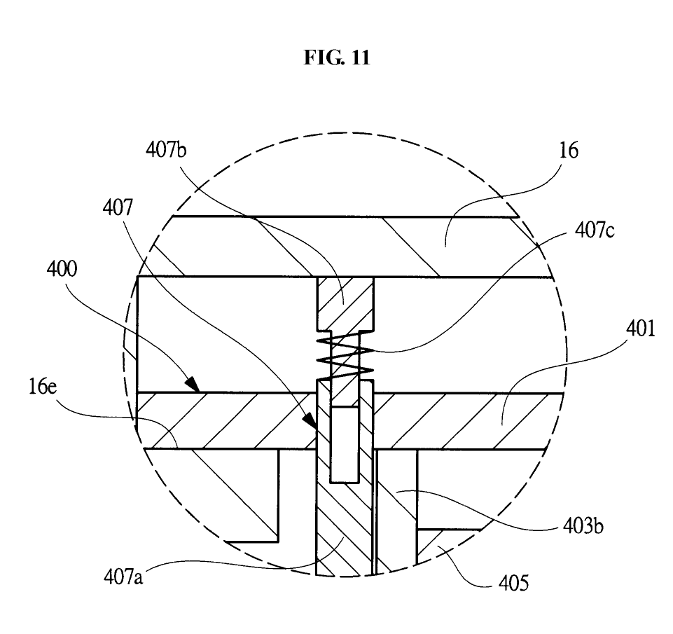

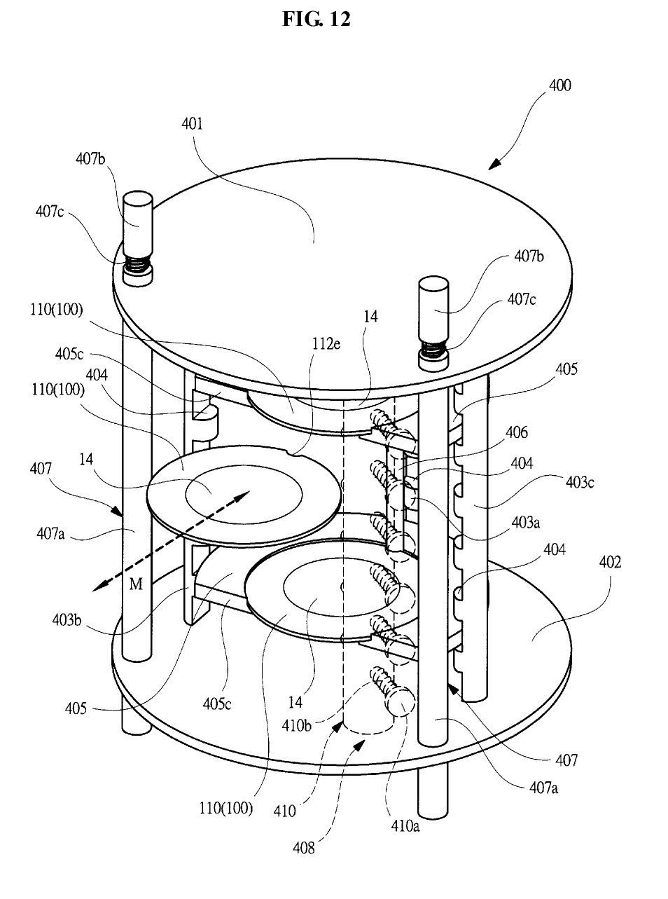

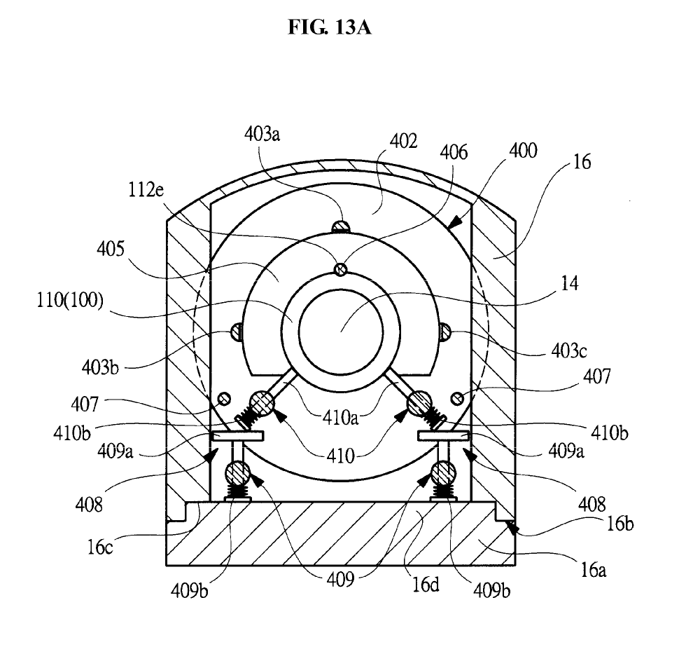

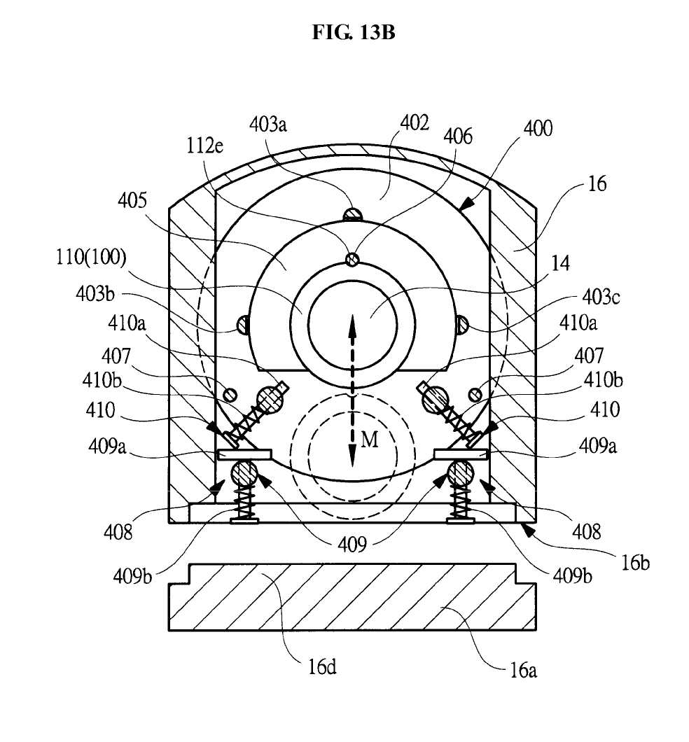

Hereinafter, a structure of the pod 16 and the attachment 400 for substrates having different diameters used in the pod 16 will be described in detail with reference to the drawings. FIGS. 9A and 9B are perspective views showing an appearance of the pod, FIG. 10 is a cross-sectional view showing a state in which an attachment for substrates having different diameters in accordance with a first embodiment is housed in the pod, FIG. 11 is an enlarged cross-sectional view showing a portion A of FIG. 10 shown in dotted lines, FIG. 12 is a perspective view showing the attachment for substrates having different diameters of FIG. 10, and FIGS. 13A and 13B are views for explaining an operation state of the attachment for substrates having different diameters of FIG. 10.

The pod 16, which is a substrate accommodation vessel, is a pod for an 8-inch wafer only, in which an 8-inch (about 20 cm) wafer (a substrate having a first size, not shown) can be housed. The pod 16 is formed of a plastic material, which does not generate particles, in a hollow shape with a side portion 16b opened. As shown in FIG. 13, an open step portion 16c is installed at the side portion 16b of the pod 16, and a mating convex portion 16d formed at the cover 16a is mated with the open step portion 16c. Accordingly, the side portion 16d may be opened/closed by the cover 16a. In addition, a seal member such as an O-ring (not shown) is installed between the open step portion 16c and the mating convex portion 16d, and thus, the inside of the pod 16 may be sealed in a vacuum state.

As shown in FIG. 10, a plurality of first support grooves 16e extending from an opening side (a front side of the drawing) to a lower side (an inner side of the drawing) are formed in the pod 16. Each of the first support grooves 16e, which supports an outer circumference of the 8-inch wafer, extends in a horizontal direction (a forward and rearward direction of the drawing). Here, seven first support grooves 16e are installed at predetermined intervals in a vertical direction (an upward and downward direction of the drawing).

The attachment 400 for substrates having different diameters shown in FIG. 12 is housed in the pod 16. The attachment 400 for substrates having different diameters is an attachment in which a 2-inch (about 5 cm) wafer (a substrate having a second size) can be housed in the pod 16 for an 8-inch wafer only. In this embodiment, the wafer 14 is a 2-inch wafer.

The attachment 400 for substrates having different diameters includes an upper plate 401 and a lower plate 402, which have a disc shape. The upper plate 401 and the lower plate 402 are formed of the same plastic material as the pod 16. Both of the upper plate 401 and the lower plate 402 have an 8-inch size (the first size), and are supported by each of the first support grooves 16e of the pod 16. Here, both of the upper plate 401 and the lower plate 402 constitute a plate-shaped member of the present invention.

A first holding column 403a, a second holding column 403b and a third holding column 403c, which are holding members (holding columns), are installed between the upper plate 401 and the lower plate 402. Each of the holding columns 403a to 403c is formed of the same plastic material as the pod 16 in a rod shape. Each upper end is fixed to the upper plate 401 and each lower end is fixed to the lower plate 402 via fastening means such as a screw (not shown). Each of the holding columns 403a to 403c is configured to have a length such that the upper plate 401 is supported by the uppermost first support groove 16e and the lower plate 402 is supported by the lowermost first support groove 16e. In addition, while at least three holding members (holding columns) may be installed, four or more holding members may be installed according to strength required for the attachment for substrates having different diameters.

A plurality of second support grooves 404 formed with cutout portions are formed at each of the holding columns 403a to 403c, and the second support grooves 404 are directed to sides of the holding columns 403a to 403c facing each other. Six second support grooves 404 are formed at predetermined intervals in a longitudinal direction of each of the holding columns 403a to 403c. Each of the second support grooves 404 supports the wafer holder 100 (see FIGS. 7 and 8), on which the wafer 14 having the second size is mounted, via the holder member 405. That is, the attachment 400 for substrates having different diameters can house six wafers 14. In addition, the holding columns 403a to 403c are installed inside the first support grooves 16e in a radial direction of the upper plate 401 and the lower plate 402. As described above, as the holding columns 403a to 403c are installed such that the wafer 14 (or the wafer holder 100) having the second size smaller than the first size can be housed in the upper plate 401 and the lower plate 402, which have the first size, the number of wafers that can be held by the attachment 400 for substrates having different diameters may be set, regardless of the interval of the first support grooves 16e of the pod 16.

Holder members 405 configured to support the wafer holders 100, on which the wafers 14 are mounted, are supported by the second support grooves 404 of the holding columns 403a to 403c. All the holder members 405 are formed of the same plastic material as the pod 16 in an annular shape, a portion of which is cut out, and fixed to the second support grooves 404 of the holding columns 403a to 403c by fastening means such as screws (not shown). Here, in FIG. 12, for the convenience of illustration, only some of the holder members 405 (for example, two) are shown.

As shown in FIG. 10, center holes 405a are formed inside the holder members 405 in a radial direction, respectively, and step portions 405b configured to support the wafer holders 100, on which the wafers 14 are mounted, are formed in inner circumferences of the center holes 405a. Accordingly, the wafer holder 100 on which the wafer 14 is mounted can be precisely positioned at the center portion of the holder member 405. In addition, as shown in FIG. 12, cutout portions 405c are formed in the holder members 405, and the cutout portions 405c communicate an outer circumference side of the holder member 405 with an inner circumference side (the center hole 405a) in a radial direction of the holder members 405. Accordingly, the arms 32 (see FIG. 1) of the substrate transfer apparatus 28 may be easily guided toward the wafer holder 100 on which the wafer 14 is mounted, and may be easily extracted from the holder member 405. Here, the wafer 14, which is held on the wafer holder 100, is transferred to the holder member 405 with the wafer holder 100 and then extracted. As described above, as the holder member 405 is provided, even without varying the attachment 400 for substrates having different diameters, only the holder member 405 is varied to deal with various sizes of wafers. In particular, in the case in which the wafer 14 is mounted on the wafer holder 100 like the first embodiment, when the wafer holder 100 is varied, even without varying the attachment 400 for substrates having different diameters, various sizes of wafers can be processed. In addition, the holder member 405 may be installed depending on necessity, or the wafer 14 or the wafer holder 100 may be directly mounted on the second support groove 404.

As shown in FIG. 13, the holder position determining rod 406 is installed around the center hole 405a of the holder member 405, and upper and lower ends of the holder position determining rod 406 are fixed to the upper plate 401 and the lower plate 402 (see FIG. 10) by fastening means such as screws (not shown). The holder position determining rod 406 is installed at a portion of the center hole 405a corresponding to the first holding column 403a, i.e., a bottom side of the pod 16 in a transfer direction (see a dotted arrow M of FIGS. 12 and 13) of the wafer holder 100 on which the wafer 14 is mounted. As described above, as the holder position determining rod 406 is provided, even when the wafer holder 100 which requires a rotational position to be determined is used as shown in FIG. 8, the rotational position can be precisely determined in the pod 16. In addition, when there is no need to determine the rotational position of the wafer 14 or the wafer holder 100, there is no need to install the holder position determining rod 406.

The holder position determining rod 406 determines a position of the rotation direction of each of the wafer holders 100 housed in the pod 16, and the notch portion 112e formed in the holder base 110 constituting the wafer holder 100 contacts the holder position determining rod 406. Accordingly, the wafer holders 100 can be precisely positioned at the attachment 400 for substrates having different diameters set in the pod 16.

As shown in FIGS. 10 to 13, a pair of telescopic rod-shaped members 407, which are fixing members to penetrate the upper plate 401 and the lower plate 402, are installed at the upper plate 401 and the lower plate 402 constituting the attachment 400 for substrates having different diameters. The rod-shaped members 407 are disposed at the side portions 16b of the pod 16, and the attachment 400 for substrates having different diameters is set at a predetermined position in the pod 16 to be fixed thereto. That is, the rod-shaped members 407 fix the upper plate 401 and the lower plate 402 to the first support grooves 16e of the pod 16, respectively.

Both of the rod-shaped members 407 have the same shape. The rod-shaped member 407 includes a main body 407a extending between the upper plate 401 and the lower plate 402, a movable part 407b installed at a side of the upper plate 401 and movable with respect to the main body 407a in a longitudinal direction thereof, and a coil spring 407c configured to press the movable part 407b with respect to the main body 407a in a direction separating therefrom. Accordingly, when a predetermined load is not applied in the longitudinal direction of the rod-shaped member 407 (a natural state), the rod-shaped member 407 is elongated by a spring force of the coil spring 407c. In addition, when a predetermined load is applied in the longitudinal direction of the rod-shaped member 407, the rod-shaped member 407 is contracted against the spring force of the coil spring 407c.

Accordingly, in a state in which the rod-shaped members 407 are contracted, as the attachment 400 for substrates having different diameters is set in the pod 16, the rod-shaped members 407 are supported in the pod 16 and fixed thereto. As a result, the attachment 400 for substrates having different diameters is securely fixed in the pod 16. In addition, the rod-shaped member, which is a fixing member, is not limited to the above-mentioned shape but may be a rod-shaped member including, for example, a main body having a female-threaded portion formed at an end thereof, and a movable part having a threaded part formed at an end thereof, which are threadedly engaged to be expanded and contracted. Further, as mating holes (not shown) in which the rod-shaped members 407 are mated are installed at the pod 16, the attachment 400 for substrates having different diameters can be more securely fixed in the pod 16.

As shown in FIGS. 12 and 13, a pressing member 408 configured to press the wafer 14 held by the holding columns 403a to 403c via the holder member 405 and the wafer holder 100 is installed at the attachment 400 for substrates having different diameters and the pod 16. The pressing member 408 presses the holder base 110 in a radial direction thereof, and is configured to mate the notch portion 112e with the holder position determining rod 406. Accordingly, the wafer 14 can be stably held in the pod 16, and further, positioning precision of the wafer holder 100 with respect to the pod 16 in the rotational direction can be improved.

The pressing member 408 includes a pair of first pressing units 409 installed at the pod 16, and a pair of second pressing units 410 installed at the upper plate 401 and the lower plate 402 of the attachment 400 for substrates having different diameters. In addition, in FIG. 12, for the convenience of illustration, only one second pressing unit 410 is shown in dotted lines.

The first pressing unit 409 includes a movable plate 409a moved by opening/closing the cover 16a of the pod 16. The movable plate 409a moves forward against a spring force of a first spring 409b as the cover 16a is closed, and moves rearward by the spring force of the first spring 409b as the cover 16a is opened.

The second pressing unit 410 includes a retainer 410a moved according to movement of the movable plate 409a of the first pressing unit 409. The retainer 410a moves forward against a spring force of a second spring 410b as the movable plate 409a moves forward (the cover 16a is closed), and moves rearward by the spring force of the second spring 410b as the movable plate 409a moves rearward (the cover 16a is opened). Then, as the cover 16a is closed to move the retainer 410a forward, the retainer 410a securely presses the holder base 110. Meanwhile, as the cover 16a is opened to move the retainer 410a rearward, the retainer 410a is separated from the holder base 110. When the retainer 410a is separated from the holder base 110, as shown in a dotted arrow M of FIG. 13B, the wafer holder 100 on which the wafer 14 is mounted can enter the attachment 400 for substrates having different diameters, i.e., the wafer 14 can enter the pod 16.

<Method of Forming SiC Epitaxial Film>

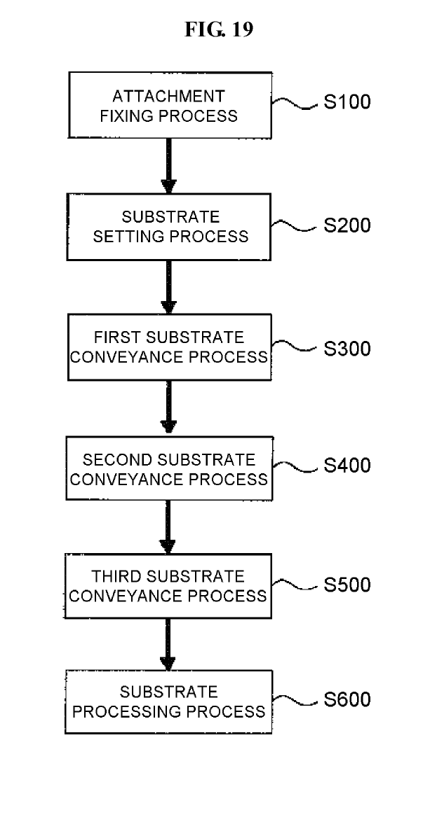

Hereinafter, as one of a process of manufacturing a semiconductor device using the semiconductor manufacturing apparatus 10, for example, a method of manufacturing (processing) a substrate such as the wafer 14 formed of SiC, on which a SiC epitaxial film is formed, will be described with reference to FIG. 19. In addition, in the following description, operations of components constituting the semiconductor manufacturing apparatus 10 are controlled by a controller 152.

First, as shown in FIG. 10, the pod 16 and the attachment 400 for substrates having different diameters are prepared. Next, the attachment 400 for substrates having different diameters is housed in the pod 16 from the side portion 16b of the pod 16. Here, the upper plate 401 is supported by the uppermost end of the first support grooves 16e and the lower plate 402 is supported by the lowermost end of the first support grooves 16e. Next, the attachment 400 for substrates having different diameters is fixed in the pod 16 by the rod-shaped members 407 (an attachment fixing process S100 of FIG. 19). In addition, the attachment fixing process may be performed by an automatic apparatus such as a robot (not shown) or may be manually performed by an operator.

Next, the wafer holders 100 on which the wafers 14 are mounted are sequentially transferred to the holder members 405 of the attachment 400 for substrates having different diameters fixed in the pod 16, respectively. Here, the notch portion 112e of the holder base 110 is mated with the holder position determining rod 406 of the attachment 400 for substrates having different diameters. Accordingly, a rotational position of the wafer holder 100, on which the wafer 14 is mounted, with respect to the attachment 400 for substrates having different diameters is determined. Next, as shown in FIG. 13, when the cover 16a is covered toward the side portion 16b of the pod 16, the mating convex portion 16d is mated with the open step portion 16c. Accordingly, the mating convex portion 16d operates the first pressing units 409 to move the movable plates 409a forward, respectively. In addition, as the movable plates 409a move forward, the second pressing units 410 are operated to move the retainers 410a, respectively, pressing the holder base 110. As the side portion 16b is covered by the cover 16a, the inside of the pod 16 is closed and the wafer holder 100 is stably supported. Accordingly, housing (setting) of the wafer 14 and the wafer holder 100 in the pod 16 is completed (a substrate setting process S200 of FIG. 19). Further, when the pod 16 is closed, for example, the inside of the pod 16 is vacuumed by a vacuum pump (not shown) to remove particles from the pod 16. Furthermore, the substrate setting process may be performed by an automatic apparatus such as a robot (not shown) or may be manually performed by an operator.

Next, as shown in FIG. 1, the plurality of pods 16 passed through the substrate setting process are mounted on the carrier CT pulled by the operator, and the pods 16 are transferred to the pod stage 18 of the semiconductor manufacturing apparatus 10. Next, the pods 16 are set on the pod stage 18 by the operator, and thus, a first substrate transfer process (S300 of FIG. 19) is completed. In addition, in the first substrate transfer process, for example, the plurality of pods 16 may be mounted on a self-propelled carrier (an automatic transfer apparatus) and automatically set on the pod stage 18.

Next, when the first substrate transfer process is completed, the pod transfer apparatus 20 is operated to convey the pod 16 from the pod stage 18 to the pod receiving shelf 22 and store the pod 16 thereon. Next, the pod 16 stored on the pod receiving shelf 22 is transferred and set at the pod opener 24 by the pod transfer apparatus 20, the cover 16a of the pod 16 is opened by the pod opener 24, and the number of wafers 14 (the wafer holders 100) received in the pod 16 is detected by the substrate number detector 26. Then, the substrate transfer apparatus 28 is operated to extract the wafer holders 100 on which the wafers 14 are mounted from the pod 16 and sequentially transfer the wafer holders 100 to the boat 30 (a second substrate transfer process S400 of FIG. 19).

When the plurality of wafers 14 are charged and stacked on the boat 30, the boat 30 on which the wafers 14 are held is transferred into the reaction chamber 44 by an elevation operation of the elevation frame 114 and the elevation shaft 124 due to rotation of the elevation motor M, that is, the boat is loaded. When the boat 30 is completely transferred into the reaction chamber 44, the seal cap 102 seals the reaction chamber 44, and thus, hermetical sealing of the reaction chamber 44 is held to complete a third substrate transfer process (a boat loading process S500 of FIG. 19).

After loading the boat 30 into the reaction chamber 44, the vacuum exhaust apparatus 220 is driven to vacuum-exhaust (vacuum-discharge) the reaction chamber 44 such that a pressure in the reaction chamber 44 reaches a predetermined pressure (a vacuum level). Here, the pressure in the reaction chamber 44 is measured by the pressure sensor and the APC valve 214 in communication with the first gas exhaust port 90 and the second gas exhaust port 390 is feedback-controlled based on the measured pressure.

In addition, a current is applied to the induction coil 50 such that a temperature of the wafer 14 and a temperature in the reaction chamber 44 reach a predetermined temperature, and thus, the heater 48 is heated. Here, a conduction state to the induction coil 50 is feedback-controlled based on temperature information detected by the temperature sensor such that the temperature in the reaction chamber 44 reaches a predetermined temperature distribution (for example, a uniform temperature distribution). Next, the boat 30 is rotated by the rotary mechanism 104, and thus, the wafers 14 are rotated in the reaction chamber 44.

After that, the MFCs 211a and 211b and the valves 212a and 212b are controlled, and thus, a silicon atom-containing gas (a film-forming gas) and a chlorine atom-containing gas (en etching gas), which contribute to form a SiC epitaxial film, are supplied from the gas supply sources 210a and 210b. Then, reactive gases are injected toward the wafers 14 in the reaction chamber 44 through the first gas supply ports 68 of the first gas supply nozzles 60.

Further, opening degrees of the MFCs 211d and 211e corresponding to a carbon atom-containing gas and H₂ gas, which is a reducing gas, are controlled to predetermined flow rates, and then, the valves 212d and 212e are controlled. Then, the reactive gases flow through the second gas line 260. Accordingly, the reactive gases are injected toward the wafers 14 in the reaction chamber 44 through the second gas supply ports 72 of the second gas supply nozzles 70.

The reactive gases injected through the first gas supply ports 68 and the second gas supply ports 72 flow along the inner circumference side of the heater 48 in the reaction chamber 44 to be exhausted to the outside from the first gas exhaust port 90 via the gas exhaust pipe 230. The reactive gases supplied through the first gas supply ports 68 and the second gas supply ports 72 are mixed just after the injection, and contact the wafers 14 formed of SiC during passing through the inside of the reaction chamber 44, and thus, the SiC epitaxial film is formed on the surfaces of the wafers 14.

In addition, the MFC 211f and the valve 212f are controlled such that Ar gas (a rare gas), which is an inert gas from the fourth gas supply source 210f, is adjusted to a predetermined flow rate to be supplied between the insulating material 54 and the reaction tube 42 via the third gas line 240 and the third gas supply port 360. The Ar gas supplied from the third gas supply port 360 flows between the insulating material 54 and the reaction tube 42 to be exhausted through the second gas exhaust port 390. After that, when the reactive gases are exposed to the wafers 14 and a predetermined time elapses, supply control of the reactive gases is stopped. A series of processes thus far, i.e., processes of forming a SiC epitaxial film on the surfaces of the wafers 14 through supply of the reactive gases, constitutes a substrate processing process of the present invention (S600 of FIG. 19).

Next, an inert gas is supplied from the inert gas supply source, a space inside the heater 48 in the reaction chamber 44 is replaced with the inert gas, and the pressure in the reaction chamber 44 is returned to a normal pressure.

After the inside of the reaction chamber 44 is returned to the normal pressure, the elevation motor M is rotated to lower the seal cap 102, and the furnace port 144 of the processing furnace 40 is opened. Accordingly, in a state in which the annealed (film-formed) wafers 14 are held on the boat 30 via the wafer holders 100, the wafers 14 are unloaded to the outside of the reaction tube 42 from the lower side of the manifold 36, i.e., the boat is unloaded. The wafers 14 held on the boat 30 are on standby in the load lock chamber LR until the wafers 14 are cooled.

After that, when the wafers 14 are cooled to a predetermined temperature, the substrate transfer apparatus 28 is operated to extract the wafer holders 100 on which the wafers 14 are mounted from the boat 30. Next, the wafers 14 are transferred and transferred to the attachment 400 for substrates having different diameters disposed in the empty pod 16 set at the pod opener 24. Then, the pod transfer apparatus 20 is operated so that the pod 16 in which the wafers 14 are housed is transferred to the pod receiving shelf 22 or the pod stage 18. As a result, a series of operations of the semiconductor manufacturing apparatus 10 are completed.

### Typical Effects of First Embodiment

According to the technical spirit described with reference to the first embodiment, at least one of a plurality of effects described below will be provided.

(1) According to the first embodiment, the upper plate 401 and the lower plate 402 supported by the first support grooves 16e that can support the 8-inch (first size) wafer, and the holding columns 403a to 403c each including the second support grooves 404 installed at the upper plate 401 and the lower plate 402 and capable of supporting the wafer 14, which is the 2-inch (second size) wafer smaller than the first size (if necessary, via the wafer holder 100 and the holder member 405) are provided. Accordingly, the downsized wafers 14 having the second size can be housed in the pod 16 corresponding to the wafers having the first size, and the pod 16, which is a transfer system, may be standardized to reduce costs of the semiconductor manufacturing apparatus 10. In addition, since a large-sized processing furnace 40 in comparison with the size of the wafers 14 to be processed can be used, the wafers 14 can be substantially spaced apart from the gas supply nozzles 60 and 70, and the reactive gases can be sufficiently mixed before arrival at the wafer 14, improving film-forming precision on the wafers 14.

(2) According to the first embodiment, the upper plate 401 is installed at the upper end of the holding columns 403a to 403c, the lower plate 402 is installed at the lower end of the holding columns 403a to 403c, and the holding columns 403a to 403c are installed inside the first support grooves 16e in the radial direction of the upper plate 401 and the lower plate 402. Accordingly, the holding columns 403a to 403c can become compact and the pod 16 in which the attachment 400 for substrates having different diameters is housed can be lightweight. In addition, an interval between the second support grooves 404 may be arbitrarily set regardless of an interval between the first support grooves 16e. Further, since contact between the attachment 400 for substrates having different diameters and the pod 16 may occur between the upper plate 401 and the first support groove 16e and between the lower plate 402 and the first support groove 16e, the attachment 400 for substrates having different diameters and the pod 16 do not require such high machining precision. Accordingly, the semiconductor manufacturing apparatus 10 may be further reduced in cost.

(3) According to the first embodiment, since a pair of rod-shaped members 407 are installed at the upper plate 401 and the lower plate 402, and the upper plate 401 and the lower plate 402 are fixed to the pod 16 including the first support grooves 16e by the rod-shaped members 407, shaking of the attachment 400 for substrates having different diameters in the pod 16 upon transfer of the pod 16 can be prevented. In this case, as the mating hole mated with the rod-shaped member 407 is installed in the pod 16, the attachment 400 for substrates having different diameters can be securely fixed to the pod 16.

(4) According to the first embodiment, since the rod-shaped members 407 are extendible and installed to penetrate the upper plate 401 and the lower plate 402, the attachment 400 for substrates having different diameters can be precisely fixed to a predetermined position in the pod 16.

(5) According to the first embodiment, since at least three holding columns 403a to 403c are installed and the second support grooves 404 are installed at sides of the holding columns 403a to 403c facing each other, the holding columns 403a to 403c can be lightweight due to the second support grooves 404 while minimizing the number of holding columns 403a to 403c. Accordingly, weight lightening of the attachment 400 for substrates having different diameters is possible.

(6) According to the first embodiment, since the holder member 405 supported by the second support grooves 404 of the holding columns 403a to 403c and including the step portion 405b supporting the wafer 14 is installed, a diameter of the step portion 405b is varied, for example, within a range of 2 inches to 4 inches so that various diameters of wafers can be easily processed.

(7) According to the first embodiment, since the holder base 110 is supported by the holder member 405 with the wafer 14 held on the holder base 110, the holder base 110 between the wafer 14 and the holder member 405 may be varied to an arbitrary shape in consideration of, for example, a flowing state (a film-forming state) of the reactive gases.

(8) According to the first embodiment, in a state in which the wafers 14 are held on the holder base 110 including the communication holes 112a to 112c corresponding to the boat columns 31a to 31c of the boat 30 used in processing of the wafers 14 and the notch portion 112e configured to determine positions of the boat columns 31a to 31c, as the wafers 14 are housed in the pod 16 including the first support grooves 16e, and the upper plate 401 and the lower plate 402 include the holder position determining rod 406 to contact the notch portion 112e and the holder position determining rod 406, the holder base 110 is positioned with respect to the pod 16. Accordingly, the holder base 110 can be precisely positioned with respect to the boat 30, and the concentration of the reactive gases arriving at the wafer 14 can be uniformized in the entire lower surface 14a of the wafer 14.

(9) According to the first embodiment, since the pressing member 408 configured to press the wafer 14 supported by the holding columns 403a to 403c is installed, the wafer 14 can be fixed via the holder base 110, and the shaking of the wafer 14 upon transfer of the pod 16 can be prevented.

(10) According to the first embodiment, as the semiconductor manufacturing apparatus 10 including the attachment 400 for substrates having different diameters is used in the process of processing a substrate in a method of manufacturing a semiconductor device, the method of manufacturing the semiconductor device has at least one of the plurality of effects.

(11) According to the first embodiment, as the semiconductor manufacturing apparatus 10 including the attachment 400 for substrates having different diameters is used in the process of processing a substrate in a method of manufacturing a SiC epitaxial film, the method of manufacturing the SiC epitaxial film has at least one of the plurality of effects.

### Second Embodiment

Hereinafter, a second embodiment of the present invention will be described in detail with reference to the accompanying drawings. In addition, components of the second embodiment having the same functions as the first embodiment will be designated by the same reference numerals, and detailed description thereof will be omitted.

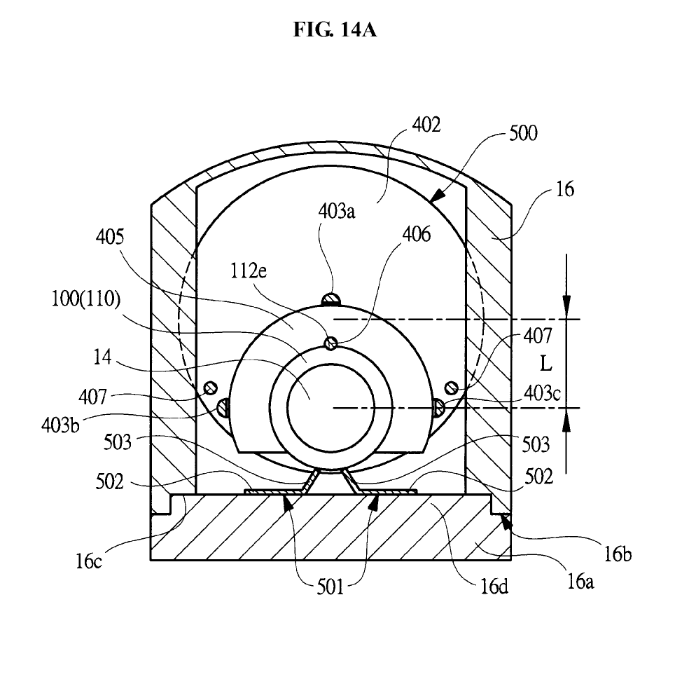

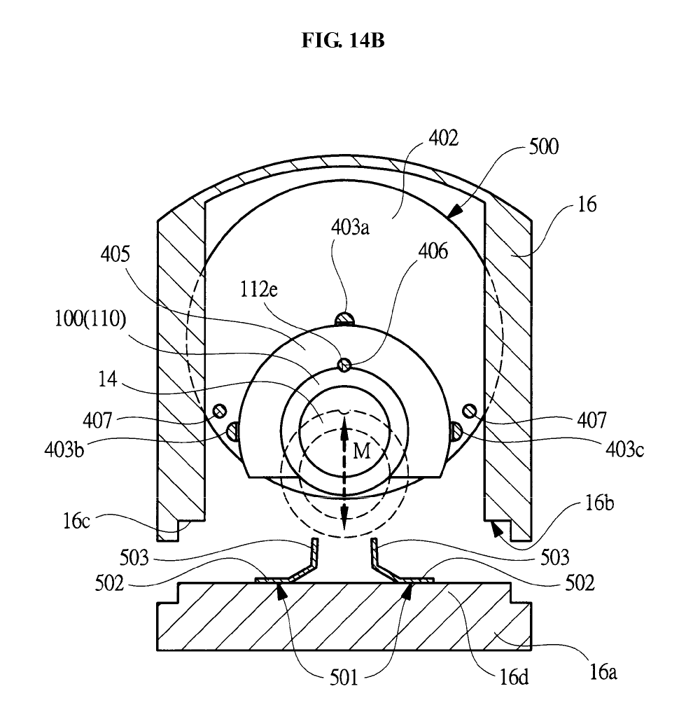

FIGS. 14A and 14B show a structure of an attachment for substrates having different diameters in accordance with the second embodiment, corresponding to FIG. 13.

As shown in FIG. 14A, an attachment 500 for substrates having different diameters in accordance with the second embodiment is distinguished from the first embodiment in that a wafer holder 100 on which the wafer 14 is mounted is offset (deviated) toward a side portion 16b of a pod 16 by a distance L. That is, a center position of the wafer 14 is disposed adjacent to a side of the cover 16a of the pod 16 in comparison with a center position of the 8-inch wafer when the 8-inch (a first size) wafer is supported by the first support grooves 16e. Accordingly, in the attachment 500 for substrates having different diameters, a second pressing unit 410 (see FIG. 13) is omitted. In addition, the second embodiment is distinguished in that, instead of the first pressing unit 409 (see FIG. 13) installed at the pod 16, a pair of spring members (pressing members) 501 are installed at the mating convex portion 16d of the cover 16a.

The spring members 501 are formed of an elastic material such as a soft plastic material, which does not generate particles, in a shape of a plate to which stages bent a plurality of times are attached, and include fixing main bodies 502 and front ends 503. The fixing main bodies 502 of the spring members 501 are fixed to a substantially central portion of the mating convex portion 16d via fastening means such as screws (not shown). In addition, the front ends 503 of the spring members 501 securely presses the holder base 110.

Accordingly, as shown in FIG. 14A, in a state in which the cover 16a is closed, the front ends of the spring member 501 contact the holder base 110 to securely press the holder base 110. In addition, as shown in FIG. 14B, in a state in which the cover 16a is open, the front ends 503 of the spring member 501 are separated from the holder base 110 so that, as shown in a dotted arrow M, the wafer holder 100 on which the wafer 14 is mounted can enter the attachment 500 for substrates having different diameters, i.e., the wafer 14 can enter the pod 16.

### Typical Effects of Second Embodiment

The technical spirit described in the second embodiment may have substantially the same effects as the first embodiment. In addition, in the second embodiment, since contact portions of the front ends 503 of the spring members 501 may be disposed at the same positions as outer diameter portions of the upper plate 401 and the lower plate 402, the pod and the cover for an 8-inch (a first size) wafer can be used as they are, and standardization may be further advanced. Further, since a structure of the pressing member can be simplified in comparison with the first embodiment, the semiconductor manufacturing apparatus 10 can be reduced in cost.

### Third Embodiment

Hereinafter, a third embodiment of the present invention will be described in detail with reference to the accompanying drawings. In addition, components having the same functions as the other embodiments will be designated by the same reference numerals, and detailed description thereof will be omitted.

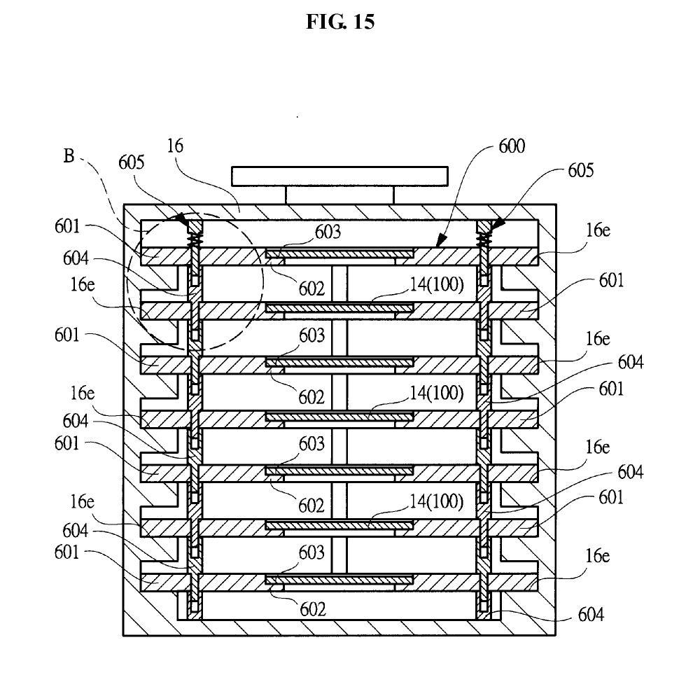

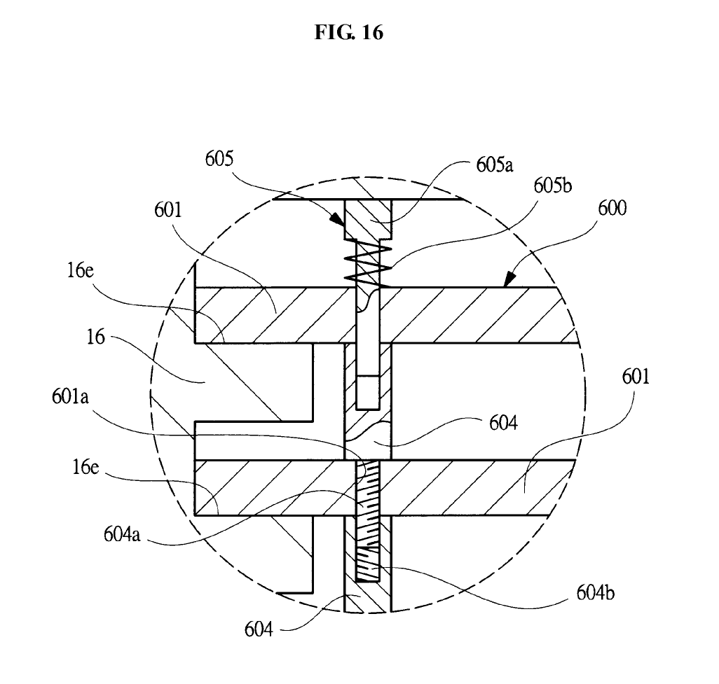

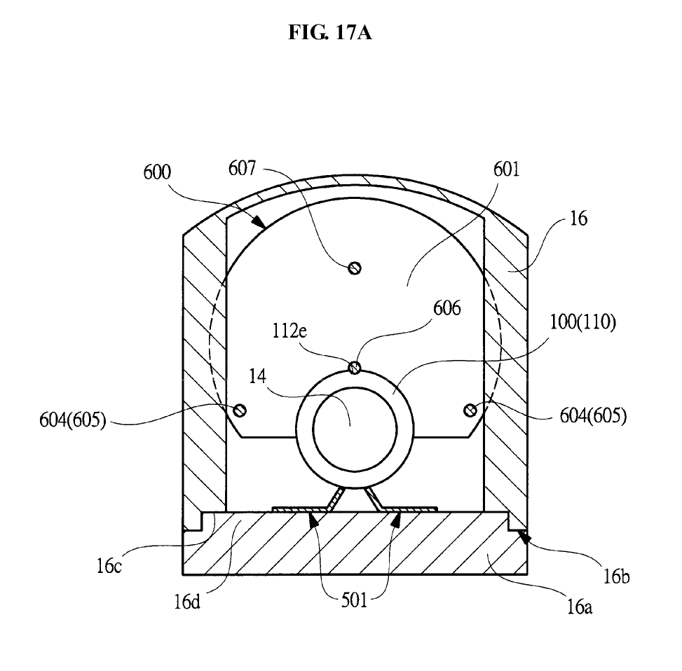

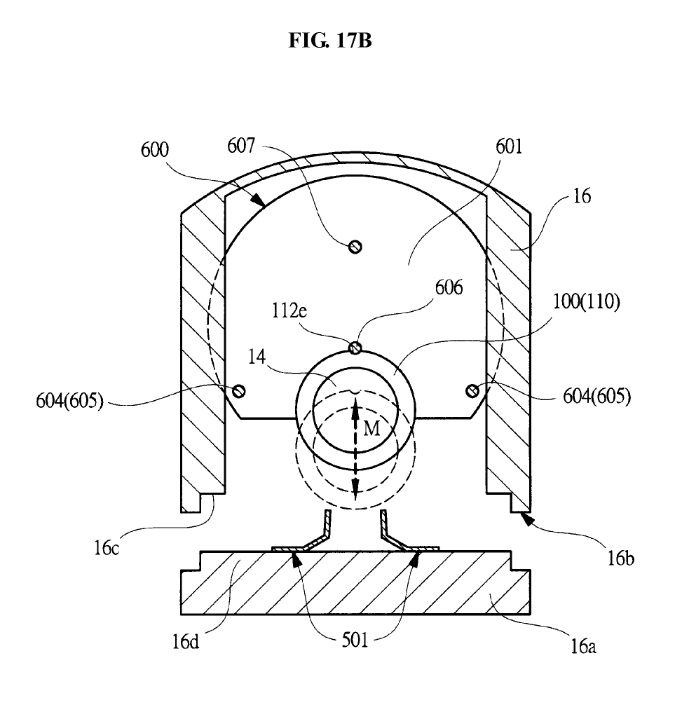

FIG. 15 is a view corresponding to FIG. 10 showing a structure of an attachment for substrates having different diameters in accordance with a third embodiment, FIG. 16 is an enlarged cross-sectional view showing a portion B of FIG. 15 shown in dotted lines, and FIGS. 17A and 17B are views for explaining an operation state of the attachment for substrates having different diameters of FIG. 15.

As shown in FIG. 15, an attachment 600 for substrates having different diameters includes plate-shaped members 601 supported by first support grooves 16e installed at a pod 16, respectively. The plate-shaped members 601 have the same shape, and similar to the holder member 405 (see FIG. 10) of the embodiments, have an annular shape formed with a cutout portion in which the wafer 14 enters (a lower side of FIG. 17).

A holding part 602, which is a holding member, configured to support the wafer holder 100, on which the wafer 14 is mounted, is integrally installed inside the plate-shaped member 601 in a radial direction thereof. In addition, a second support groove 603 configured to support the wafer holder 100 on which the wafer 14 is mounted is installed at an inner circumference of the holding part 602, i.e., an inner circumference of the plate-shaped member 601. As described above, in the third embodiment, the plate-shaped member, the holding member and the second support groove of the present invention are integrated as the plate-shaped member 601 having an annular shape.

As shown in FIG. 16, fixing rods 604 having threaded portions 604a and female threaded portions 604b are installed between the plate-shaped members 601. The fixing rods 604 are installed at left and right sides of the attachment 600 for substrates having different diameters to form a pair so that the plurality of plate-shaped members 601 are stacked and held at predetermined intervals. The threaded portions 604a of the fixing rods 604 penetrate screw through-holes 601a formed in the plate-shaped members 601 to be threadedly engaged with the female threaded portions adjacent thereto, holding the plate-shaped members 601 at predetermined intervals. In addition, a length of each of the fixing rods 604, aside from the threaded portions 604a and the female threaded portions 604b, is set to the same length as an interval of the adjacent first support grooves 16e. Accordingly, as the attachment 600 for substrates having different diameters is merely housed in the pod 16, the plate-shaped members 601 are supported by the first support grooves 16e corresponding thereto, respectively.

Here, the lowermost fixing rod 604 of the fixing rods 604 contacts the pod 16, without the threaded portion 604a. In addition, a fixing member 605 is installed at an upper side (in the drawing) of the fixing rod 604. The fixing member 605 fixes the attachment 600 for substrates having different diameters in the pod 16 to be operated, like the rod-shaped member 407 (see FIG. 12) of the embodiments. The fixing member 605 includes the fixing rod 604 without the female threaded portion 604b, a movable rod 605a movable with respect to the fixing rod 604 in an axial direction thereof, and a coil spring 605b configured to press the movable rod 605a in a direction spaced apart from the fixing rod 604. In addition, the fixing member 605 is not limited to the above-mentioned shape but may include, for example, a fixing rod 604 having a female threaded portion and a movable rod (not shown) threadedly engaged with the female threaded portion 604b.

As shown in FIG. 17, a holder position determining rod 606 configured to contact a notch portion 112e formed at the holder base 110 is installed to penetrate a substantially central portion of the plate-shaped member 601. Upper and lower ends of the holder position determining rod 606 are fixed to the plate-shaped members 601 disposed at the uppermost end and the lowermost end of the plate-shaped members 601 by fastening means such as screws (not shown). As described above, as the holder position determining rod 606 is installed at a substantially central portion of each of the plate-shaped members 601, similar to the second embodiment, the wafer holder 100 on which the wafer 14 is mounted is offset to a side of the side portion 16b of the pod 16, and the cover 16a of the pod 16 is standardized for an 8-inch (first size) wafer. However, in the attachment 600 for substrates having different diameters according to the third embodiment, similar to the first embodiment, a center of the plate-shaped member 601 may coincide with a center of the wafer 14, and the pressing member 408 (see FIG. 13) constituted by the first pressing unit 409 and the second pressing unit 401 may be employed.

A support rod 607 configured to support a side of each of the plate-shaped members 601 spaced apart from the fixing rods 604 is installed between the fixing rods 604 in a circumferential direction of each of the plate-shaped members 601 at a rear surface side (an upper side of the drawing) of the holder position determining rod 606. The support rod 607 has the same configuration as each of the fixing rods 604 and cooperates with the fixing rods 604 to hold the plate-shaped members 601 at predetermined intervals. In addition, both ends of the support rod 607 are configured to go beyond the plate-shaped member 601 not to contact the pod 16, and thus, the attachment 600 for substrates having different diameters can be easily housed in the pod 16.

### Typical Effects of Third Embodiment

The technical spirit described in the third embodiment may have substantially the same effects as the other embodiments. In addition, in the third embodiment, in comparison with the above-mentioned embodiments, the holding columns, which are holding members, may be omitted. Further, since the plate-shaped members 601 are supported by the first support grooves 16e of the pod 16, respectively, the number of wafers 14 housed in the pod 16 can be increased and efficiency in a film-forming process can be increased.

### Fourth Embodiment

Hereinafter, a fourth embodiment of the present invention will be described in detail with reference to the accompanying drawings. In addition, components having the same functions as the other embodiments will be designated by the same reference numerals, and detailed description thereof will be omitted.

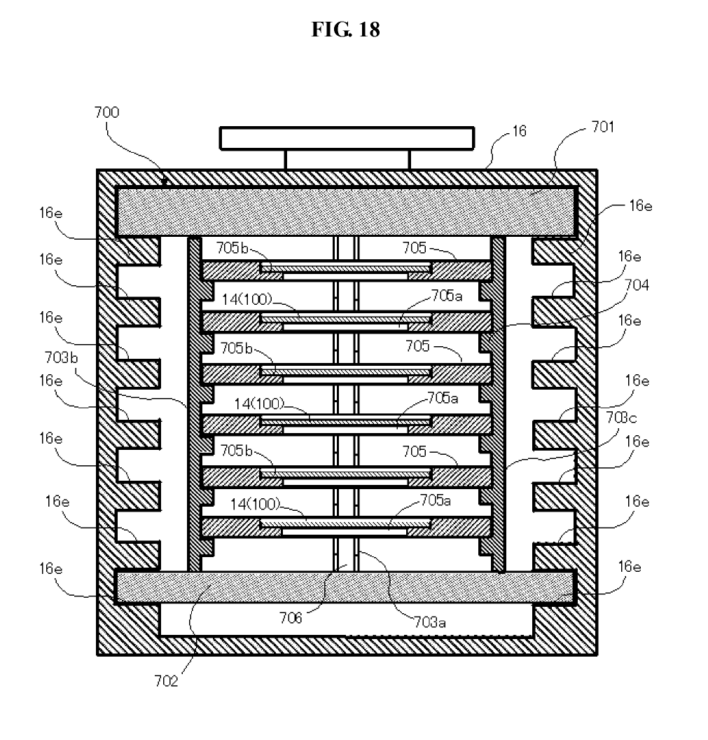

FIG. 18 is a view corresponding to FIG. 10 showing a structure of an attachment for substrates having different diameters in accordance with the fourth embodiment.

As shown in FIG. 18, an attachment 700 for substrates having different diameters according to the fourth embodiment includes a plate-shaped member 701, which is an upper plate mated with a space between the uppermost end of the first support grooves 16e installed in the pod 16 and the pod 16, and similarly, a plate-shaped member 702, which is a lower plate mated with a space between the lowermost end of the first support grooves 16e and the first support groove 16e disposed just one above the lowermost end.

A method of holding a wafer holder is provided to offset and hold the wafer holder 100 on which the wafer 14 is mounted to the side portion 16b of the pod 16, similar to the second embodiment, and the cover 16a of the pod 16 is standardized for an 8-inch (first size) wafer.

In addition, the plate-shaped members 701 and 702 are not limited to the disc shape shown in FIG. 12 but may have a rectangular shape. In addition, an end of the plate-shaped member may be tapered for the purpose of easy mating.

### Typical Effects of Fourth Embodiment

The technical spirit described in the fourth embodiment may have substantially the same effects as the above-mentioned embodiments. In addition, in the fourth embodiment, since there is no need for complex machining in comparison with the above-mentioned embodiments, the attachment for substrates having different diameters can be securely fixed to the pod with a low cost and a simple structure. Further, since a means for fixing the attachment to the pod is used for mating with the pod, vibrations of the attachment due to vibrations of the pod caused by movement thereof can be prevented and generation of particles in the pod can be prevented.

Hereinabove, while the invention performed by the inventor has been described in detail based on the embodiments, the present invention is not limited to the above-mentioned embodiments but may be variously varied without departing from the spirit of the present invention. For example, in the embodiments, while the attachment for substrates having different diameters according to the present invention is exemplarily applied to an apparatus for forming a SiC epitaxial film (a substrate processing apparatus), the technical spirit of the present invention may be applied to another type of substrate processing apparatus for processing a wafer having a smaller diameter than that in which the pod 16 can be housed.

In addition, in the first and second embodiments, the wafer 14 is supported by the second support grooves 404 of the holding columns 403a to 403c, which are holding members, via the wafer holder 100 (the holder base 110) and the holder member 405, and in the third embodiment, the wafer 14 is supported by the second support grooves 603 formed in the inner circumference of the holding part (a holding member) 602 of the plate-shaped member 601 via the wafer holder 100 (the holder base 110). However, the present invention is not limited thereto but the wafer 14 may be directly supported by the second support grooves 404 of the holding columns 403a to 403c or the wafer 14 may be supported by the second support grooves 603 of the plate-shaped member 601.

The present invention includes at least the following embodiments.

[Supplementary Note 1]

An attachment for substrates having different diameters including: a plate-shaped member supported by a first support groove capable of supporting a substrate having a first size; and a holding member installed at the plate-shaped member and including a second support groove capable of supporting a substrate having a second size smaller than the first size.

[Supplementary Note 2]

The attachment for substrates having different diameters according to additional statement 1, wherein the plate-shaped member comprises an upper plate having the first size and installed at an upper end of the holding member; and a lower plate having the first size and installed at a lower end of the holding member, and the holding member is supported by an inner side of the first support groove between the upper plate and the lower plate in a radial direction of the upper plate and the lower plate.

[Supplementary Note 3]

The attachment for substrates having different diameters according to additional statement 1, wherein the plate-shaped member has an annular shape with a cutout portion at an entrance side of the substrate having the second size, and the second support groove of the holding member is disposed at an inner circumference of the plate-shaped member.

[Supplementary Note 4]

The attachment for substrates having different diameters according to additional statement 3, wherein the plate-shaped member is stacked in plural, and a fixing rod having a threaded portion and disposed between the plurality of plate-shaped members to maintain a uniform interval therebetween.

[Supplementary Note 5]

The attachment for substrates having different diameters according to any one of additional statements 1 to 4, further including a fixing member installed at the plate-shaped member to fix the plate-shaped member to a substrate accommodation vessel including the first support groove.

[Supplementary Note 6]

The attachment for substrates having different diameters according to additional statement 5, wherein the fixing member includes a telescopic rod-shaped member installed to penetrate the plate-shaped member.

[Supplementary Note 7]

The attachment for substrates having different diameters according to additional statement 1 or 2, wherein the holding member includes at least three holding columns, each of the at least three holding columns having the second support groove facing one another.

[Supplementary Note 8]

The attachment for substrates having different diameters according to additional statement 7, further including a holder member having a step portion supported by the second support groove of each of the three holding columns and configured to support the substrate having the second size.

[Supplementary Note 9]

The attachment for substrates having different diameters according to additional statement 8, wherein the holder member supports a substrate holder configured to hold the substrate having the second size.

[Supplementary Note 10]

The attachment for substrates having different diameters according to any one of additional statements 1 to 9, wherein the substrate having the second size is accommodated in a substrate accommodation vessel including the first support groove, the substrate having the second size being held by a substrate holder including: a communication hole corresponding to a boat column of a boat used upon processing of the substrate of the second size; and a notch portion configured to determine a position with respect to the boat column, and the plate-shaped member includes a holder position determining rod, and by contacting the holder position determining rod to the notch portion, a position of the substrate holder is determined with respect to the substrate accommodation vessel.

[Supplementary Note 11]

The attachment for substrates having different diameters according to any one of additional statements 1 to 10, further including a pressing member configured to press the substrate having the second size supported by the holding member.

[Supplementary Note 12]

The attachment for substrates having different diameters according to additional statement 11, wherein the pressing member includes a movable plate installed at the substrate accommodation vessel including the first support groove and configured to move according to opening/closing of the cover of the substrate accommodation vessel; and a retainer installed at the plate-shaped member and configured to move according to a movement of the movable plate.

[Supplementary Note 13]

The attachment for substrates having different diameters according to additional statement 11, wherein the pressing member a spring member installed at the cover of the substrate accommodation vessel including the first support groove, and the spring member presses the substrate having the second size by closing the cover.

[Supplementary Note 14]

The attachment for substrates having different diameters according to additional statement 11, wherein a center position of the substrate having the second size is disposed closer to a cover of the substrate accommodation vessel than a center position of the substrate having the first size when the substrate having the first size is supported by the first support groove.

[Supplementary Note 15]

A substrate processing apparatus including: an attachment for substrates having different diameters including: a plate-shaped member supported by a first support groove capable of supporting a substrate having a first size; and a holding member installed at the plate-shaped member and including a second support groove capable of supporting a substrate having a second size smaller than the first size; a substrate accommodation vessel having the first support groove and configured to accommodate the attachment; a reaction vessel configured to process the substrates; and a vessel introduction part configured to introduce the substrate accommodation vessel from an outside; a transfer mechanism installed between the vessel introduction part and the reaction vessel and configured to transfer the substrate accommodation vessel from the vessel introduction part into the reaction vessel.

[Supplementary Note 16]

A method of manufacturing a semiconductor device, including: preparing an attachment for substrates having different diameters including a plate-shaped member supported by a first support groove capable of supporting a substrate having a first size; and a holding member installed at the plate-shaped member and including a second support groove capable of supporting a substrate having a second size smaller than the first size, and fixing the attachment in a substrate accommodation vessel including the first support groove; charging the substrate having the second size into the attachment fixed in the substrate accommodation vessel; transferring the substrate accommodation vessel where the substrate having the second size accommodated to a vessel introduction part of a substrate processing apparatus; operating a transfer mechanism of the substrate processing apparatus to transfer the substrate accommodation vessel in the vessel introduction part toward a reaction vessel where the substrate having the second size is to be processed; operating a substrate transfer apparatus of the substrate processing apparatus to transfer the substrates having the second size in the substrate accommodation vessel into a boat, and transferring the boat to the reaction vessel; and supplying a reactive gas through a gas nozzle in the reaction vessel and heating an inside of the reaction vessel using a heater to process the substrate having the second size.

The present invention can be widely applied in a manufacturing field of manufacturing a semiconductor device or a substrate on which a SiC epitaxial film is formed.

What is claimed is:

1. An attachment for substrates having different diameters, comprising:
a plate-shaped member supported by a first support groove capable of supporting a substrate having a first size; and
a holding member installed at the plate-shaped member and including a second support groove capable of supporting a substrate having a second size smaller than the first size.

2. The attachment of claim 1, wherein the plate-shaped member comprises an upper plate having the first size and installed at an upper end of the holding member; and a lower plate having the first size and installed at a lower end of the holding member, and
the holding member is supported by an inner side of the first support groove between the upper plate and the lower plate in a radial direction of the upper plate and the lower plate.

3. An attachment for substrates having different diameters, comprising:
a plate-shaped member having an annular shape and supported by a first support groove capable of supporting a substrate having a first size; and
a holding member installed at the plate-shaped member and supporting a substrate having a second size smaller than the first size.

4. The attachment of claim 3, comprising a plurality of the plate-shaped member, and further comprising a fixing rod having a threaded portion and disposed between the plurality of plate-shaped members to maintain a uniform interval therebetween.

5. The attachment of claim 1, further comprising a fixing member installed at the plate-shaped member to fix the plate-shaped member to a substrate accommodation vessel including the first support groove.

6. The attachment of claim 5, wherein the fixing member comprises a telescopic rod-shaped member installed to penetrate the plate-shaped member.

7. The attachment of claim 1, wherein the holding member comprises at least three holding columns, each of the at least three holding columns having the second support groove facing one another.

8. The attachment of claim 7, further comprising a holder member having a step portion supported by the second support groove of each of the three holding columns and configured to support the substrate having the second size.

9. The attachment of claim 8, wherein the holder member supports a substrate holder configured to hold the substrate having the second size.

10. The attachment of claim 1, wherein the substrate having the second size is accommodated in a substrate accommodation vessel including the first support groove, the substrate having the second size being held by a substrate holder including: a communication hole corresponding to a boat column of a boat used upon processing of the substrate of the second size; and a notch portion configured to determine a position with respect to the boat column, and
the plate-shaped member comprises a holder position determining rod, and by contacting the holder position determining rod to the notch portion, a position of the substrate holder is determined with respect to the substrate accommodation vessel.

11. The attachment of claim 1, wherein a center position of the substrate having the second size is disposed closer to a cover of the substrate accommodation vessel than a center position of the substrate having the first size when the substrate having the first size is supported by the first support groove.

12. The attachment of claim 11, further comprising a pressing member configured to press the substrate having the second size supported by the holding member.

13. The attachment of claim 12, wherein the pressing member comprises a movable plate installed at the substrate accommodation vessel including the first support groove and configured to move according to opening/closing of the cover of the substrate accommodation vessel; and a retainer installed at the plate-shaped member and configured to move according to a movement of the movable plate.

14. The attachment of claim 13, wherein the pressing member comprises a spring member installed at the cover of the substrate accommodation vessel including the first support groove, and the spring member presses the substrate having the second size by closing the cover.

15. The attachment of claim 2, wherein each of the upper plate and the lower plate fits the first support groove.

16. A substrate processing apparatus comprising:
an attachment for substrates having different diameters including: a plate-shaped member supported by a first support groove capable of supporting a substrate having a first size; and a holding member installed at the plate-shaped member and including a second support groove capable of supporting a substrate having a second size smaller than the first size;
a substrate accommodation vessel having the first support groove and configured to accommodate the attachment;
a reaction vessel configured to process the substrates; and
a vessel introduction part configured to introduce the substrate accommodation vessel from an outside;
a transfer mechanism installed between the vessel introduction part and the reaction vessel and configured to transfer the substrate accommodation vessel from the vessel introduction part into the reaction vessel.

17. A method of manufacturing a semiconductor device, comprising:
preparing an attachment for substrates having different diameters including a plate-shaped member supported by a first support groove capable of supporting a substrate having a first size; and a holding member installed at the plate-shaped member and including a second support groove capable of supporting a substrate having a second size smaller than the first size, and fixing the attachment in a substrate accommodation vessel including the first support groove;
charging the substrate having the second size into the attachment fixed in the substrate accommodation vessel;
transferring the substrate accommodation vessel where the substrate having the second size accommodated to a vessel introduction part of a substrate processing apparatus;
operating a transfer mechanism of the substrate processing apparatus to transfer the substrate accommodation vessel in the vessel introduction part toward a reaction vessel where the substrate having the second size is to be processed;
operating a substrate transfer apparatus of the substrate processing apparatus to transfer the substrates having the second size in the substrate accommodation vessel into a boat, and transferring the boat to the reaction vessel; and
supplying a reactive gas through a gas nozzle in the reaction vessel and heating an inside of the reaction vessel using a heater to process the substrate having the second size.
